(19) United States
(12) Patent Application Publication
(10) Pub. No.: US 2024/0036689 A1
(43) Pub. Date: Feb. 1, 2024

(54) DISPLAY DEVICE INCLUDING AN INPUT SENSOR

(71) Applicant: SAMSUNG DISPLAY CO., LTD., Yongin-Si (KR)

(72) Inventors: Kicheol Kim, Yongin-Si (KR); Wonkyu Kwak, Yongin-Si (KR); Gyeongnam Bang, Yongin-Si (KR)

(21) Appl. No.: 18/319,970

(22) Filed: May 18, 2023

(30) Foreign Application Priority Data
Jul. 26, 2022 (KR) 10-2022-0092703

(51) Int. Cl. G06F 3/044

(52) U.S. Cl. CPC G06F 3/0445; G06F 3/0446; G06F 2203/04107; G06F 2203/04111

(57) ABSTRACT

A display device includes a display panel including a long side extending in a first direction and a short side extending in a second direction crossing the first direction and an input sensor disposed on the display panel. The input sensor includes first sensing electrodes each extending in the first direction along the long side, second sensing electrodes each extending in the second direction along the short side, first signal lines electrically connected to the first sensing electrodes, and second signal lines electrically connected to the second sensing electrodes. Each of the first sensing electrodes is electrically connected to two or more first signal lines among the first signal lines, and at least one of the two or more first signal lines overlaps the first sensing electrodes in a plan view.

This U.S. non-provisional patent application claims priority under 35 U.S.C. § 119 to Korean Patent Application No. 10-2022-0092703, filed in the Korean Intellectual Property Office on Jul. 26, 2022, the contents of which are hereby incorporated by reference in their entirety.

### TECHNICAL FIELD

The present disclosure relates to a display device. More particularly, the present disclosure relates to a display device including an input sensor.

### DISCUSSION OF THE RELATED ART

Multimedia electronic devices, such as televisions, mobile phones, tablet computers, vehicle navigation units, and game consoles, include a display device to display images. Display devices are also commonly provided inside a vehicle so serve as instrument display screens, rear and side view screens, and infotainment screens.

Often, display devices include an input sensor that provides a touch-based input method allowing users to easily and intuitively input information or commands in addition to the usual input methods such as using a button, a keyboard, a mouse, etc.

### SUMMARY

A display device includes a display panel including a long side extending in a first direction and a short side extending in a second direction crossing the first direction and an input sensor disposed on the display panel. The input sensor includes first sensing electrodes each extending in the first direction along the long side, second sensing electrodes each extending in the second direction along the short side, first signal lines electrically connected to the first sensing electrodes, and second signal lines electrically connected to the second sensing electrodes. Each of the first sensing electrodes is electrically connected to two or more first signal lines among the first signal lines, and at least one of the two or more first signal lines overlaps the first sensing electrodes in a plan view.

The input sensor may include a first area, a second area, and a third area, which are distinguished from each other in the first direction, each of the first sensing electrodes may include a first portion overlapping the first area in a plan view, a second portion overlapping the second area in a plan view, and a third portion overlapping the third area in a plan view, and the two or more first signal lines may include a first-first signal line electrically connected to the first portion, a first-second signal line electrically connected to the second portion, and a first-third signal line electrically connected to the third portion.

The first area may be disposed at one end of the input sensor, and each of the first-first, first-second, and first-third signal lines may overlap the first sensing electrodes in a plan view.

The first area may be disposed at one end of the input sensor, the first-first signal line might not overlap the first sensing electrodes in a plan view, and each of the first-second signal line and the first-third signal line may overlap the first sensing electrodes in a plan view.

At least one of the two or more first signal lines may extend in the second direction.

Each of the first sensing electrodes may include a plurality of first sensing patterns arranged in the first direction and a plurality of extension patterns extending from the plurality of first sensing patterns, and each of the second sensing electrodes may include a plurality of second sensing patterns arranged in the second direction and a plurality of bridge patterns electrically connecting the plurality of second sensing patterns to one another.

The first signal lines may be electrically connected to the first sensing patterns.

Positions at which the first signal lines are electrically connected to the first sensing patterns may be the same as each other in the first, second, and third areas.

The first sensing electrodes may include a first row sensing electrode, a second row sensing electrode, and a third row sensing electrode, which are spaced apart from each other in the second direction, and the first-first signal lines respectively electrically connected to the first, second, and third row sensing electrodes might not overlap each other in a plan view.

The input sensor may further include a sensing controller disposed adjacent to a lower side of the first sensing electrodes and the second sensing electrodes, in the second direction.

The input sensor may include a first area and a second area distinguished from the first area in the first direction, each of the first sensing electrodes may include a first portion overlapping the first area in a plan view and a second portion overlapping the second area in a plan view, and the two or more first signal lines may include a first-first signal line electrically connected to the first portion and a first-second signal line electrically connected to the second portion.

The input sensor may further include a sensing controller disposed adjacent to a lower portion of the first area in the second direction, and the first area may be disposed between the second area and the sensing controller.

Each of the first sensing electrodes may include a plurality of first sensing patterns arranged in the first direction and a plurality of extension patterns extending from the plurality of first sensing patterns, each of the second sensing electrodes may include a plurality of second sensing patterns arranged in the second direction and a plurality of bridge patterns connecting the plurality of second sensing patterns, the first sensing patterns, the plurality of extension patterns, and the second sensing patterns may be disposed at a first layer, and the plurality of bridge patterns, the first signal lines, and the second signal lines may be disposed at a second layer under the first layer.

The first-first signal line may be electrically connected to first sensing pattern disposed at one end of the first portion adjacent to the sensing controller among the first sensing patterns, and the first-first signal line might not overlap the first sensing electrodes in a plan view.

The first-second signal line may be electrically connected to one of first sensing patterns disposed at the second portion among the first sensing patterns, and the first-second signal line may overlap the first sensing electrodes in a plan view.

The first-second signal line may be electrically connected to first sensing pattern disposed at one end of the second portion adjacent to the first portion among the first sensing patterns, and the first-second signal line may overlap the first sensing electrodes in a plan view.

At least one of the two or more first signal lines may extend in the first direction.

A display device includes a display panel displaying an image and an input sensor including a sensing area including a first area and a second area distinguished from the first area in a first direction and a non-sensing area adjacent to the sensing area. The input sensor includes a first sensing electrode extending in the first direction, a second sensing electrode extending in a second direction crossing the first direction, a first-first signal line electrically connected to the first sensing electrode in the first area, a first-second signal line electrically connected to the first sensing electrode in the second area, and a second signal line disposed in the non-sensing area and electrically connected to the second sensing electrode. At least one of the first-first and first-second signal lines overlaps the first sensing electrode in a plan view.

The input sensor may include first conductive patterns disposed on the display panel, a first sensor insulating layer disposed on the first conductive patterns, second conductive patterns disposed on the first sensor insulating layer, and a second sensor insulating layer disposed on the second conductive patterns, the first sensing electrode may include the second conductive patterns, and the first-first and first-second signal lines may include the first conductive patterns.

A display device includes a display panel displaying an image and an input sensor including a sensing area including a first area, a second area, and a third area, which are distinguished from each other in a first direction and a non-sensing area adjacent to the sensing area. The input sensor includes a first sensing electrode extending in the first direction and disposed in the first, second, and third areas, a second sensing electrode extending in a second direction crossing the first direction and disposed in one of the first, second, and third areas, a first-first signal line disposed in the first area and electrically connected to the first sensing electrode, a first-second signal line disposed in the second area and electrically connected to the first sensing electrode, a first-third signal line disposed in the third area and electrically connected to the first sensing electrode, and a second signal line disposed in the non-sensing area and electrically connected to the second sensing electrode. At least one of the first-first, first-second, and first-third signal lines overlaps the first sensing electrode in a plan view.

### BRIEF DESCRIPTION OF THE DRAWINGS

The above and other aspects of the present disclosure will become readily apparent by reference to the following detailed description when considered in conjunction with the accompanying drawings wherein:

FIG. 1 is a plan view of an electronic device according to an embodiment of the present disclosure;

FIG. 2 is an exploded perspective view of some components of an electronic device according to an embodiment of the present disclosure;

FIG. 3A is a cross-sectional view of an electronic device according to an embodiment of the present disclosure;

FIG. 3B is a cross-sectional view of an electronic device according to an embodiment of the present disclosure;

FIG. 4A is a cross-sectional view of a display device according to an embodiment of the present disclosure;

FIG. 4B is a cross-sectional view of a display device according to an embodiment of the present disclosure;

FIG. 5 is an enlarged cross-sectional view of a display device according to an embodiment of the present disclosure;

FIG. 6A is a plan view of an input sensor according to an embodiment of the present disclosure;

FIG. 6B is an enlarged plan view of a portion of the input sensor of FIG. 6A;

FIG. 7A is an enlarged plan view of an area RR of FIG. 6A;

FIG. 7B is a cross-sectional view of an input sensor according to an embodiment of the present disclosure;

FIG. 8A is an enlarged plan view of an area TT of FIG. 6A;

FIG. 8B is a cross-sectional view of an input sensor according to an embodiment of the present disclosure;

FIG. 9A is an enlarged plan view of a first area of FIG. 6A;

FIG. 9B is an enlarged plan view of a first area of FIG. 6A;

FIG. 9C is an enlarged plan view of a first area of FIG. 6A;

FIG. 9D is an enlarged plan view of a first area of FIG. 6A;

FIG. 10 is a plan view of an input sensor according to an embodiment of the present disclosure;

FIG. 11 is a plan view of an input sensor according to an embodiment of the present disclosure;

FIG. 12A is an enlarged plan view of an area TT′ of FIG. 11;

FIG. 12B is a cross-sectional view of an input sensor according to an embodiment of the present disclosure; and

FIG. 13 is a plan view of an input sensor according to an embodiment of the present disclosure.

### DETAILED DESCRIPTION

The present disclosure may be variously modified and realized in many different forms, and thus specific embodiments will be exemplified in the drawings and described in detail hereinbelow. However, the present disclosure should not necessarily be seen as limited to the specific disclosed forms, and may be construed to include all modifications, equivalents or replacements included in the spirit and scope of the present disclosure.

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

In the present disclosure, when an element is referred to as being “directly disposed” to another element, there are no intervening elements present between a laver, film region, or substrate and another layer, film, region, or substrate. For example, the term “directly disposed” may mean that two layers or two elements are disposed without employing additional adhesive therebetween.

Like numerals may refer to like elements throughout the specification and the drawings. As used herein, the term “and/or” may include any and all combinations of one or more of the associated listed items.

It will be understood that, although the terms first, second, etc. may be used herein to describe various elements, these elements should not necessarily be limited by these terms. These terms are used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Hereinafter, embodiments of the present disclosure will be described with reference to accompanying drawings.

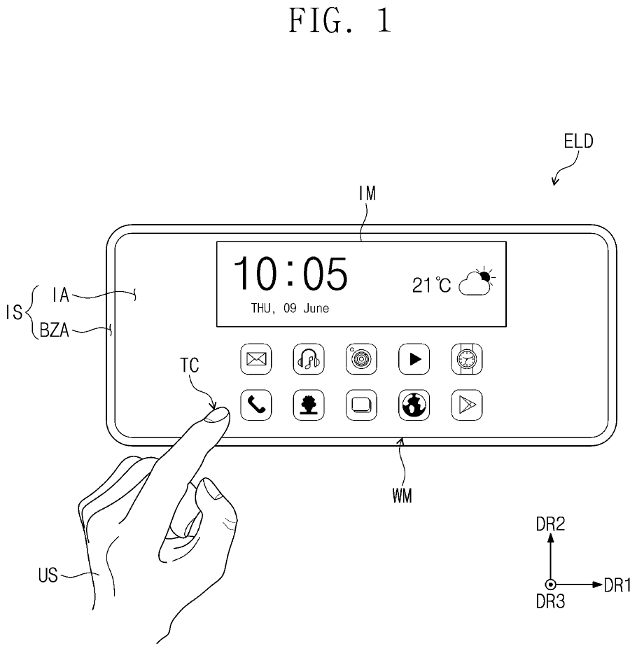

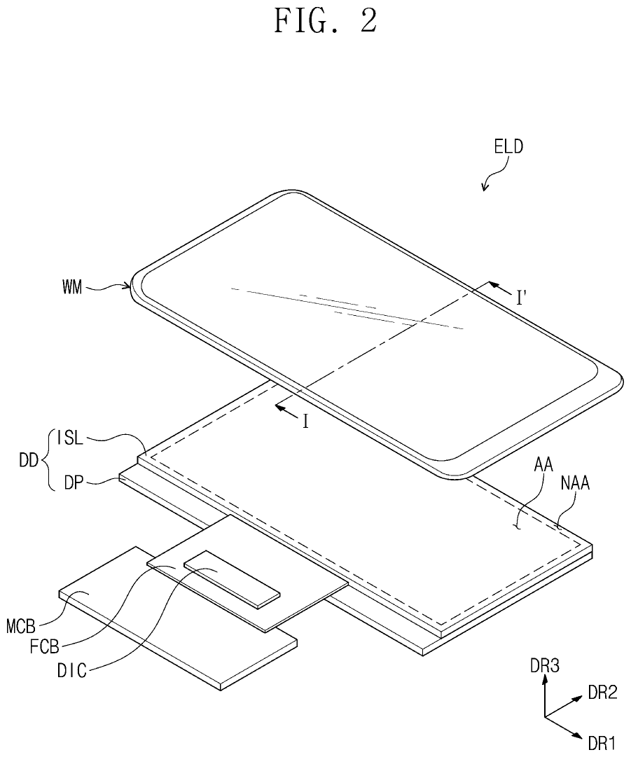

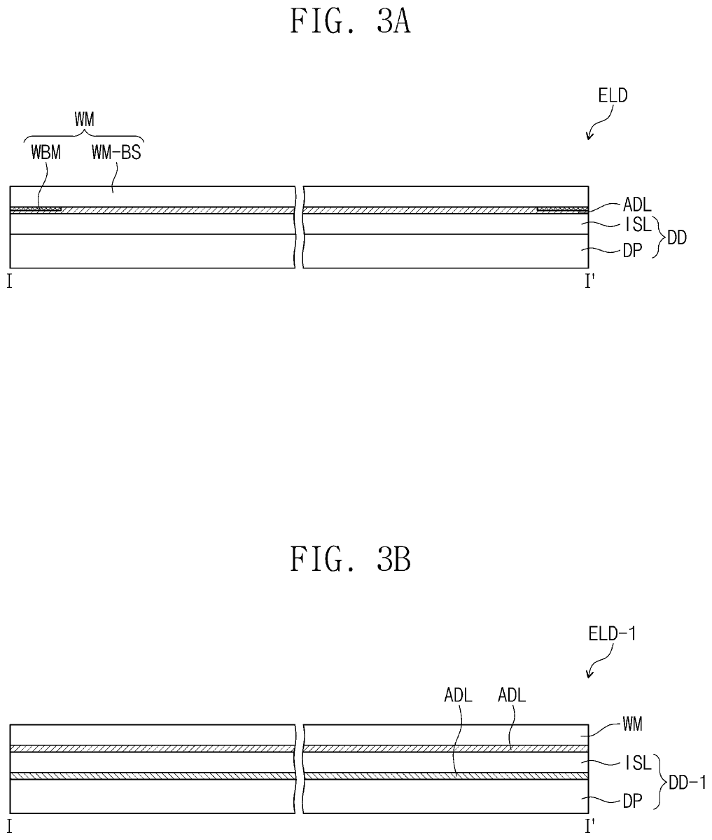

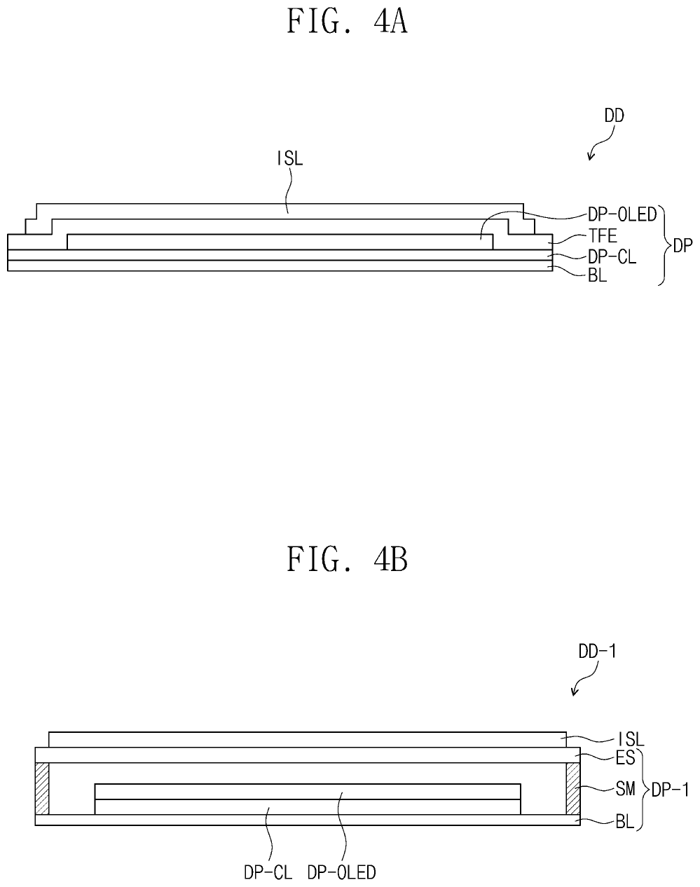

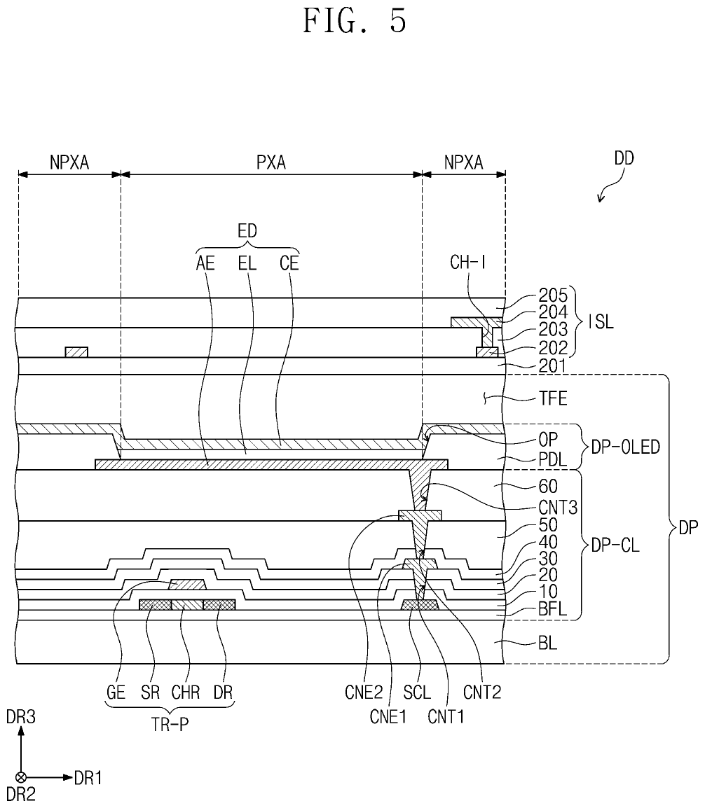

FIG. 1 is a plan view of an electronic device ELD according to an embodiment of the present disclosure. FIG. 2 is an exploded perspective view of some components of the electronic device ELD according to an embodiment of the present disclosure. FIG. 3A is a cross-sectional view of the electronic device ELD according to an embodiment of the present disclosure. FIG. 3B is a cross-sectional view of an electronic device ELD-1 according to an embodiment of the present disclosure. FIG. 4A is a cross-sectional view of a display device DD according to an embodiment of the present disclosure. FIG. 4B is a cross-sectional view of a display device DD-1 according to an embodiment of the present disclosure.

Referring to FIGS. 1 and 2, the electronic device ELD may be activated in response to electrical signals. The electronic device ELD may include various embodiments. For example, the electronic device ELD may be a large-sized display device applied to a television set, a computer monitor, an outdoor digital billboard, or a vehicle screen, however, the present disclosure should not necessarily be limited thereto or thereby. The electronic device ELD may be applied to a small and medium-sized display device, such as a personal computer, a notebook computer, a personal digital assistant, a game console, a portable electronic item, a digital camera, or the like.

The electronic device ELD may display an image IM toward a third direction DR3 through a display surface IS substantially extending in each of a first direction DR1 and a second direction DR2. The display surface IS through which the image IM is displayed may correspond to a front surface of the electronic device ELD. The image IM may include a video as well as a still image.

In the present embodiment, front (or upper) and rear (or lower) surfaces of each member may be defined with respect to a direction in which the image IM is displayed. The front and rear surfaces may be opposite to each other in the third direction DR3, and a normal line direction of each of the front and rear surfaces may be substantially extended in the third direction DR3.

A separation distance between the front surface and the rear surface in the third direction DR3 may correspond to a thickness in the third direction DR3 of the electronic device ELD. Directions indicated by the first, second, and third directions DR1, DR2, and DR3 may be changed to other directions different from the directions defined in FIG. 1.

The electronic device ELD may sense an external input applied thereto. The external input may include various forms of inputs provided from beyond the electronic device ELD. The electronic device ELD, according to the present embodiment, may sense an input TC of a user US applied thereto. The input TC of the user US may be an input generated by a user's finger and may include all inputs that cause a variation in capacitance, such as an input using a user's body part. The input TC may include an input generated by a passive-type input device. The electronic device ELD may sense the input TC of the user US, which is applied to a side or rear surface of the electronic device ELD depending on a structure of the electronic device ELD, and the present disclosure should not necessarily be particularly limited thereto. In addition, the electronic device ELD, according to the present embodiment, may sense an input different from the input TC shown in FIG. 1. As an example, the input different from the input TC may include inputs generated by an input device, e.g., a stylus pen, an active pen, a touch pen, an electronic pen, or the like.

The front surface of the electronic device ELD may include an image area IA and a bezel area BZA. The image area IA may be an area through which the image IM is displayed. The user may view the image IM through the image area IA. In the present embodiment, the image area IA may have a quadrilateral shape with rounded vertices, however, this is merely an example. The image area IA may have a variety of shapes and should not necessarily be particularly limited thereto.

The bezel area BZA may be defined adjacent to the image area IA. The bezel area BZA may have a predetermined color. The bezel area BZA may at least partially surround the image area IA. Accordingly, the image area IA may have a shape defined by the bezel area BZA, however, this is merely an example, and the bezel area BZA may be disposed adjacent to only one side of the image area IA or may be omitted. The electronic device ELD, according to the present embodiment, may include various embodiments and should not necessarily be particularly limited thereto.

Referring to FIG. 2, the electronic device ELD may include the display device DD and a window WM disposed on the display device DD. The display device DD may include a display panel DP and an input sensor ISL.

The display panel DP, according to the present embodiment, may be a light-emitting type display panel, however, it should not necessarily be particularly limited thereto. For instance, the display panel DP may be an organic light emitting display panel or a quantum dot light emitting display panel. A light emitting layer of the organic light emitting display panel may include an organic light emitting material. A light emitting layer of the quantum dot light emitting display panel may include a quantum dot and/or a quantum rod. Hereinafter, the organic light emitting display panel will be described as a representative example of the display panel DP.

The input sensor ISL may be disposed on the display panel DP and may obtain coordinate information of the external input, e.g., the input TC. The input sensor ISL will be described in detail later.

The display device DD may include a main circuit board MCB, a flexible circuit film FCB, and a driving chip DIC. One or more of the main circuit board MCB, the flexible circuit film FCB, and the driving chip DIC may be omitted. The main circuit board MCB may be connected to the flexible circuit film FCB and may be electrically connected to the display panel DP. The main circuit board MCB may include a plurality of driving elements. The driving elements may include a circuit part to drive the display panel DP. The flexible circuit film FCB may be connected to the display panel DP to electrically connect the display panel DP to the main circuit board MCB. The driving chip DIC may be mounted on the flexible circuit film FCB.

The flexible circuit film FCB may be bent to allow the main circuit board MCB to face a rear surface of the display device DD. The main circuit board MCB may be electrically connected to other electronic modules of the electronic device ELD through a connector.

The driving chip DIC may include driving elements, e.g., a data driving circuit, to drive pixels of the display panel DP. In the present embodiment, one flexible circuit film FCB is shown, however, it should not necessarily be limited thereto or thereby. For example, the flexible circuit film FCB may be provided in plural, and the flexible circuit films may be connected to the display panel DP. FIG. 2 shows a structure in which the driving chip DIC is mounted on the flexible circuit film FCB, however, the present disclosure should not necessarily be limited thereto or thereby. For example, the driving chip DIC may be disposed directly on the display panel DP. A portion of the display panel DP may be bent, and a portion of the display panel DP on which the driving chip DIC is mounted may face the rear surface of the display device DD.

The input sensor ISL may be electrically connected to the main circuit board MCB via an additional flexible circuit film, however, the present disclosure should not necessarily be limited thereto or thereby. The input sensor ISL may be electrically connected to the display panel DP and may be electrically connected to the main circuit board MCB via the flexible circuit film FCB. Conductive structures may be applied to the display device DD to electrically connect the input sensor ISL to the display panel DP.

The window WM may include a transparent material that transmits the image IM. For example, a base layer of the window WM may include a glass, sapphire, or plastic material. The window WM may have a single-layer structure, however, it should not necessarily be limited thereto or thereby, and the window WM may include a plurality of layers.

The electronic device ELD may further include a case. The case may absorb impacts applied thereto from the outside and may prevent a foreign substance and moisture from entering the display device DD to protect components accommodated in the case. The electronic device ELD, according to the embodiment, may further include an electronic module including a variety of functional modules to drive the display device DD, a power supply module supplying a power required for an overall operation of the electronic device ELD, and a bracket coupled to the display device DD and/or the case to divide an inner space of the electronic device ELD.

The above-described elements may be coupled to each other by an adhesive layer. The adhesive layer may include an optically clear adhesive (OCA) film, an optically clear resin (OCR), or a pressure sensitive adhesive (PSA) film.

An anti-reflective layer may be further disposed between the window WM and the display device DD. The anti-reflective layer may reduce a reflectance with respect to an external light incident thereto from the above of the window WM. The anti-reflective layer, according to the present disclosure, may include a retarder and a polarizer. The retarder may be a film type or liquid crystal coating type and may include a λ/2 retarder (half wave plate) and/or a λ/4 retarder (quarter wave plate). The polarizer may be a film type or liquid crystal coating type. The film type retarder and polarizer may include a stretching type synthetic resin film, and the liquid crystal coating type retarder and polarizer may include liquid crystals aligned in a predetermined alignment. The retarder and the polarizer may be implemented as one polarizing film. According to an embodiment, the anti-reflective layer may include color filters that are directly disposed on the input sensor ISL or the display panel DP or that are internalized within the input sensor ISL or the display panel DP.

The display device DD may display the image in response to electrical signals and may transmit/receive information about the external input. The display device DD may include an active area AA and a peripheral area NAA. The image may be displayed through the active area AA, and the external input may be sensed in the active area AA. The active area AA and the peripheral area NAA may respectively correspond to the image area IA and the bezel area BZA shown in FIG. 1. In the following descriptions, the expression “an area/portion corresponds to another area/portion” means that “an area/portion overlaps another area/portion”, and the expression should not necessarily be limited to “an area/portion has the same area and/or the same shape as another area/portion”.

The peripheral area NAA may be defined adjacent to the active area AA. For example, the peripheral area NAA may at least partially surround the active area AA. However, this is merely an example, and the peripheral area NAA may be defined in various shapes and should not necessarily be particularly limited thereto. According to an embodiment, the active area AA of the display device DD may correspond to at least a portion of the image area IA.

Referring to FIG. 3A, the input sensor ISL may be disposed directly on the display panel DP. According to an embodiment of the present disclosure, the input sensor ISL may be formed on the display panel DP through successive processes. For example, when the input sensor ISL is disposed directly on the display panel DP, an adhesive layer might not be disposed between the input sensor ISL and the display panel DP. According to an embodiment, an adhesive layer ADL may be disposed between a display device DD and a window WM of an electronic device ELD. Referring to FIG. 3B, an adhesive layer ADL may be disposed between a display device DD and a window WM and between an input sensor ISL and a display panel DP in the electronic device ELD-1. In this case, the input sensor ISL might not be formed through the successive processes with the display panel DP and may be fixed on an upper surface of the display panel DP by the adhesive layer ADL after being formed through a separate process from the display panel DP.

As shown in FIG. 3A, the window WM may include a light blocking pattern WBM to define the bezel area BZA (refer to FIG. 1). The light blocking pattern WBM may be a colored organic layer and may be formed on a lower surface of a base layer WM-BS by a coating method.

Referring to FIG. 4A, the display panel DP may include a base layer BL, a circuit element layer DP-CL disposed on the base layer BL, a display element layer DP-OLED, and an encapsulation layer TFE. The input sensor ISL may be disposed directly on the encapsulation layer TFE.

The base layer BL may include at least one plastic film. The base layer BL may include a plastic substrate, a glass substrate, a metal substrate, or an organic/inorganic composite substrate. According to the present embodiment, the base layer BL may be a thin film glass substrate having a thickness of about tens to hundreds of micrometers. The base layer BL may have a multi-layer structure. For instance, the base layer BL may include the multi-layer structure of polyimide layer/at least one inorganic layer/polyimide layer.

The circuit element layer DP-CL may include at least one insulating layer and a circuit element. The insulating layer may include at least one inorganic layer and at least one organic layer. The circuit element may include signal lines and a driving circuit of the pixels. This will be described in detail later.

The display element layer DP-OLED may include at least a light emitting element, for example, organic light emitting diodes. The display element layer DP-OLED may further include an organic layer such as a pixel definition layer.

The encapsulation layer TFE may include a plurality of thin layers. Some thin layers may increase an optical efficiency, and the other thin layers may protect the organic light emitting diodes. The encapsulation layer TFE may have a stack structure of inorganic layer/organic layer/inorganic layer.

Referring to FIG. 4B, in the display device DD-1, a display panel DP-1 may include a base layer BL, a circuit element layer DP-CL, a display element layer DP-OLED, an encapsulation substrate ES, and a sealant SM that bonds the base layer BL and the encapsulation substrate ES. The circuit element layer DP-CL, the display element layer DP-OLED, and the encapsulation substrate ES may be disposed on the base layer BL. The sealant SM may include an organic adhesive or a frit.

The encapsulation substrate ES may be spaced apart from the display element layer DP-OLED with a predetermined gap. The gap may be filled with a desiccant or a resin material. The input sensor ISL may be provided on the encapsulation substrate ES.

FIG. 5 is an enlarged cross-sectional view of the display device DD according to an embodiment of the present disclosure.

Referring to FIG. 5, the display device DD may include the display panel DP and the input sensor ISL disposed directly on the display panel DP. For example, an adhesive layer might not be disposed between the display panel DP and the input sensor ISL. The display panel DP may include the base layer BL, the circuit element layer DP-CL, the display element layer DP-OLED, and the encapsulation layer TFE.

The base layer BL may provide a base surface on which the circuit element layer DP-CL is disposed. The base layer BL may be a rigid substrate or a flexible substrate that is bendable, foldable, or rollable. The base layer BL may be a glass substrate, a metal substrate, or a polymer substrate, however, it should not necessarily be limited thereto or thereby. According to an embodiment, the base layer BL may be an inorganic layer, an organic layer, or a composite material layer.

The base layer BL may have a multi-layer structure. For instance, the base layer BL may include a first synthetic resin layer, an inorganic layer having a single-layer or multi-layer structure, and a second synthetic resin layer disposed on the inorganic layer having the single-layer or multi-layer structure. Each of the first and second synthetic resin layers may include a polyimide-based resin, however, it should not necessarily be particularly limited thereto.

The circuit element layer DP-CL may be disposed on the base layer BL. The circuit element layer DP-CL may include an insulating layer, a semiconductor pattern, a conductive pattern, and a signal line. An insulating layer, a semiconductor layer, and a conductive layer may be formed on the base layer BL by a coating or depositing process. Then, the insulating layer, the semiconductor layer, and the conductive layer may be selectively patterned through several photolithography processes. The semiconductor pattern, the conductive pattern, and the signal line included in the circuit element layer DP-CL may be formed.

At least one inorganic layer may be formed on an upper surface of the base layer BL. The inorganic layer may include at least one of aluminum oxide, titanium oxide, silicon oxide, silicon oxynitride, zirconium oxide, and hafnium oxide. The inorganic layer may be formed in multiple layers. The inorganic layers may form a barrier layer and/or a buffer layer. In the present embodiment, the display panel DP may include a buffer layer BFL.

The buffer layer BFL may increase a coupling force between the base layer BL and the semiconductor pattern. The buffer layer BFL may include a silicon oxide layer and a silicon nitride layer, and the silicon oxide layer and the silicon nitride layer may be alternately stacked with each other.

The semiconductor pattern may be disposed on the buffer layer BFL. The semiconductor pattern may include polysilicon, however, it should not necessarily be limited thereto or thereby. The semiconductor pattern may include amorphous silicon or metal oxide.

FIG. 5 shows only a portion of the semiconductor pattern, and the semiconductor pattern may be further disposed in other areas. The semiconductor pattern may be arranged with a specific rule over the pixels. The semiconductor pattern may have different electrical properties depending on whether it is doped or not or whether it is doped with an N-type dopant or a P-type dopant. The semiconductor pattern may include a first region having high conductivity and a second region having low conductivity. The first region may be doped with the N-type dopant or the P-type dopant. A P-type transistor may include a doped region doped with the P-type dopant. The second region may be a non-doped region or may be doped at a low concentration compared with the first region.

The first region may have the conductivity greater than that of the second region and may substantially serve as an electrode or signal line. The second region may substantially correspond to an active area (or a channel area) of the transistor. In other words, a portion of the semiconductor pattern may be the active area of the transistor, and other portions of the semiconductor pattern may be a source area or a drain area of the transistor.

Each of the pixels may have an equivalent circuit that includes seven transistors, one capacitor, and a light emitting element, and the equivalent circuit may be changed in various ways. FIG. 5 shows one transistor TR-P and the light emitting element ED included in the pixel.

A source area SR, a channel area CHR, and a drain area DR of the transistor TR-P may be formed from the semiconductor pattern. The source area SR and the drain area DR may extend in opposite directions to each other from the channel area CHR in a cross-section. FIG. 5 shows a portion of a signal line SCL disposed on the same layer as the semiconductor pattern. The signal line SCL may be electrically connected to the transistor TR-P in a plan view.

A first insulating layer 10 may be disposed on the buffer layer BFL. The first insulating layer 10 may commonly overlap the pixels and may cover the semiconductor pattern. The first insulating layer 10 may be an inorganic layer and/or an organic layer and may have a single-layer or multi-layer structure. The first insulating layer 10 may include at least one of aluminum oxide, titanium oxide, silicon oxide, silicon nitride, silicon oxynitride, zirconium oxide, and hafnium oxide. In the present embodiment, the first insulating layer 10 may have a single-layer structure of a silicon oxide layer. Not only the first insulating layer 10, but also an insulating layer of the circuit element layer DP-CL described later may be an inorganic layer and/or an organic layer and may have a single-layer or multi-layer structure. The inorganic layer may include at least one of the above-mentioned materials, however, it should not necessarily be limited thereto.

A gate GE of the transistor TR-P may be disposed on the first insulating layer 10. The gate GE may be a portion of a metal pattern. The gate GE may overlap the channel area CHR. The gate GE may be used as a mask in a process of doping the semiconductor pattern.

A second insulating layer 20 may be disposed on the first insulating layer 10 and may cover the gate GE. The second insulating layer 20 may commonly overlap the pixels. The second insulating layer 20 may be an inorganic layer and/or an organic layer and may have a single-layer or multi-layer structure. In the present embodiment, the second insulating layer 20 may have a single-layer structure of a silicon oxide layer.

A third insulating layer 30 may be disposed on the second insulating layer 20. In the present embodiment, the third insulating layer 30 may have a single-layer structure of a silicon oxide layer. A first connection electrode CNE1 may be disposed on the third insulating layer 30. The first connection electrode CNE1 may be electrically connected to the signal line SCL via a contact hole CNT1 defined through the first, second, and third insulating layers 10, 20, and 30.

A fourth insulating layer 40 may be disposed on the third insulating layer 30. The fourth insulating layer 40 may have a single-layer structure of a silicon oxide layer. A fifth insulating layer 50 may be disposed on the fourth insulating layer 40. The fifth insulating layer may be an organic layer.

A second connection electrode CNE2 may be disposed on the fifth insulating layer 50. The second connection electrode CNE2 may be electrically connected to the first connection electrode CNE1 via a contact hole CNT2 defined through the fourth insulating layer 40 and the fifth insulating layer 50.

A sixth insulating layer 60 may be disposed on the fifth insulating layer 50 and may cover the second connection electrode CNE2. The sixth insulating layer 60 may be an organic layer. The display element layer DP-OLED may be disposed on the circuit element layer DP-CL. The display element layer DP-OLED may include the light emitting element ED. For example, the display element layer DP-OLED may include an organic light emitting material, a quantum dot, a quantum rod, a micro-LED, or a nano-LED. The light emitting element ED may include a first electrode AE, an emission layer EL, and a second electrode CE.

The first electrode AE may be disposed on the sixth insulating layer 60. The first electrode AE may be electrically connected to the second connection electrode CNE2 via a contact hole CNT3 defined through the sixth insulating layer 60.

A pixel definition layer PDL may be disposed on the sixth insulating layer 60 and may cover a portion of the first electrode AE. An opening OP may be defined through the pixel definition layer PDL. At least a portion of the first electrode AE may be exposed through the opening OP of the pixel definition layer PDL. In the present embodiment, an emission area PXA may be defined to correspond to the portion of the first electrode AE exposed through the opening OP. A non-emission area NPXA may at least partially surround the emission area PXA

The emission layer EL may be disposed on the first electrode AE. The emission layer EL may be disposed in the opening OP. For example, the emission layer EL may be formed in each of the pixels after being divided into plural portions. When the emission layer EL is formed in each of the pixels after being divided into plural portions, each of the emission layers EL may emit a light having at least one of blue, red, and green colors, however, it should not necessarily be limited thereto or thereby. The emission layer EL might not be divided into plural portions and may be commonly provided over the pixels. In this case, the emission layer EL may provide a blue light or a white light.

The second electrode CE may be disposed on the emission layer EL. The second electrode CE may have an integral shape and may be commonly disposed over the pixels. A common voltage may be applied to the second electrode CE, and the second electrode CE may be referred to as a common electrode.

A hole control layer may be disposed between the first electrode AE and the emission layer EL. The hole control layer may be commonly disposed in the emission area PXA and the non-emission area NPXA. The hole control layer may include a hole transport layer and may further include a hole injection layer. An electron control layer may be disposed between the emission layer EL and the second electrode CE. The electron control layer may include an electron transport layer and may further include an electron injection layer. The hole control layer and the electron control layer may be commonly formed in the plural pixels using an open mask.

The input sensor ISL may be directly formed on an upper surface of the encapsulation layer TFE through successive processes. The input sensor ISL may include a base insulating layer 201, a first conductive pattern 202, a first sensor insulating layer 203, a second conductive pattern 204, and a second sensor insulating layer 205. According to an embodiment of the present disclosure, the base insulating layer 201 may be omitted. In this case, the first conductive pattern 202 may be disposed directly on the upper surface of the encapsulation layer TFE.

Each of the first and second conductive patterns 202 and 204 may have a single-layer structure or a plurality of patterns having a multi-layer structure of layers stacked in the third direction DR3. The conductive pattern having the single-layer structure may include a metal layer or a transparent conductive layer. The metal layer may include molybdenum, silver, titanium, copper, aluminum, or alloys thereof. The transparent conductive layer may include a transparent conductive oxide, such as indium tin oxide (ITO), indium zinc oxide (IZO), zinc oxide (ZnO), indium zinc tin oxide (IZTO), or the like. In addition, the transparent conductive layer may include conductive polymer such as PEDOT, metal nanowire, graphene, or the like.

The conductive pattern having the multi-layer structure may include metal layers. The metal layers may have a three-layer structure of titanium/aluminum/titanium. The conductive layer having the multi-layer structure may include at least one metal layer and at least one transparent conductive layer.

The first sensor insulating layer 203 may cover the first conductive pattern 202, and the second sensor insulating layer 205 may cover the second conductive pattern 204. The first sensor insulating layer 203 and the second sensor insulating layer 205 have the single-layer structure, however, they should not necessarily be limited thereto or thereby. The second conductive pattern 204 may be electrically connected to the first conductive pattern 203 via a through hole CH—I.

At least one of the first sensor insulating layer 203 and the second sensor insulating layer 205 may include an inorganic layer. The inorganic layer may include at least one of aluminum oxide, titanium oxide, silicon oxide, silicon nitride, silicon oxynitride, zirconium oxide, and hafnium oxide.

One of the first sensor insulating layer 203 and the second sensor insulating layer 205 may include an organic layer. The organic layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, and a perylene-based resin.

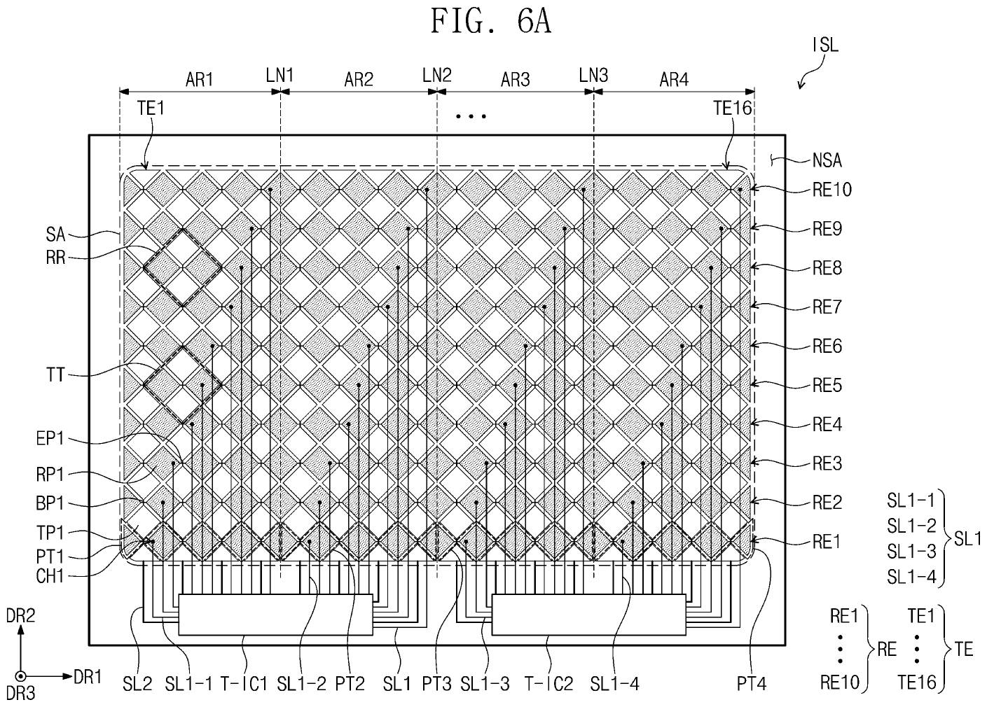

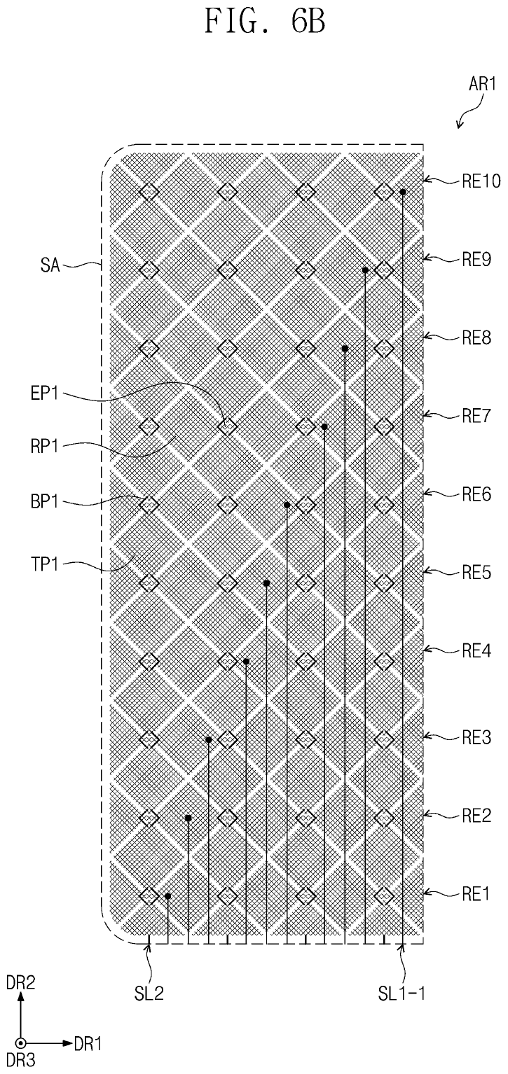

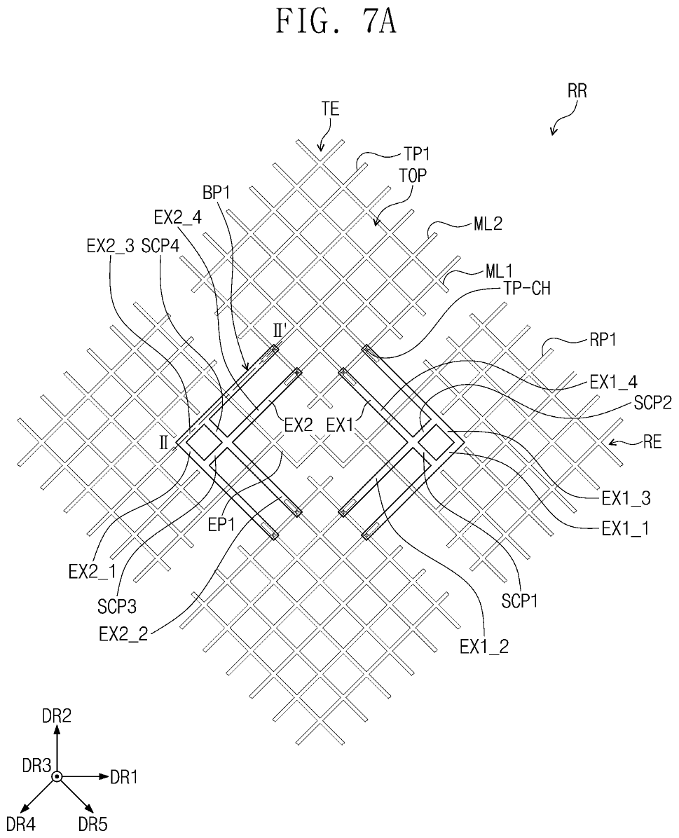

FIG. 6A is a plan view of the input sensor ISL according to an embodiment of the present disclosure. FIG. 6B is an enlarged plan view of a portion of the input sensor ISL of FIG. 6A.

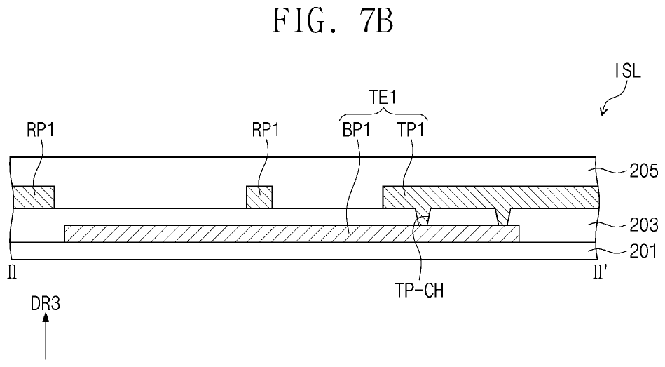

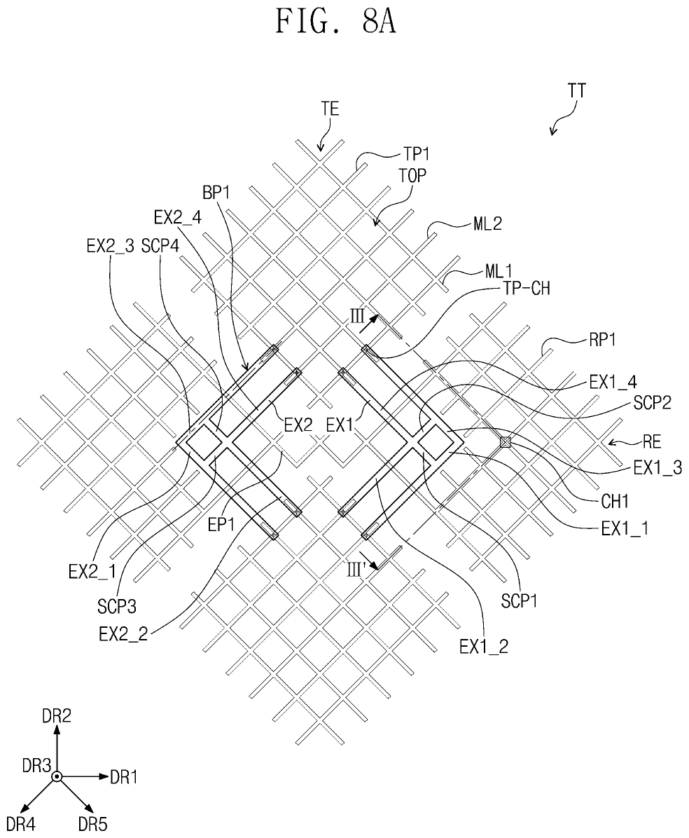

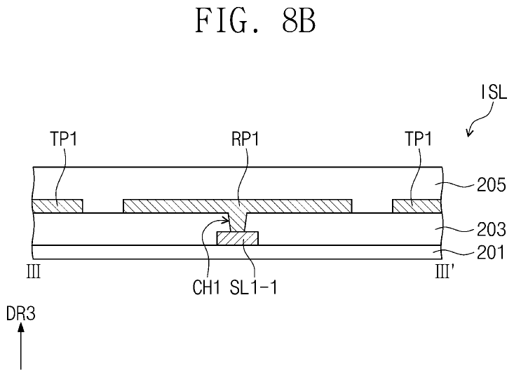

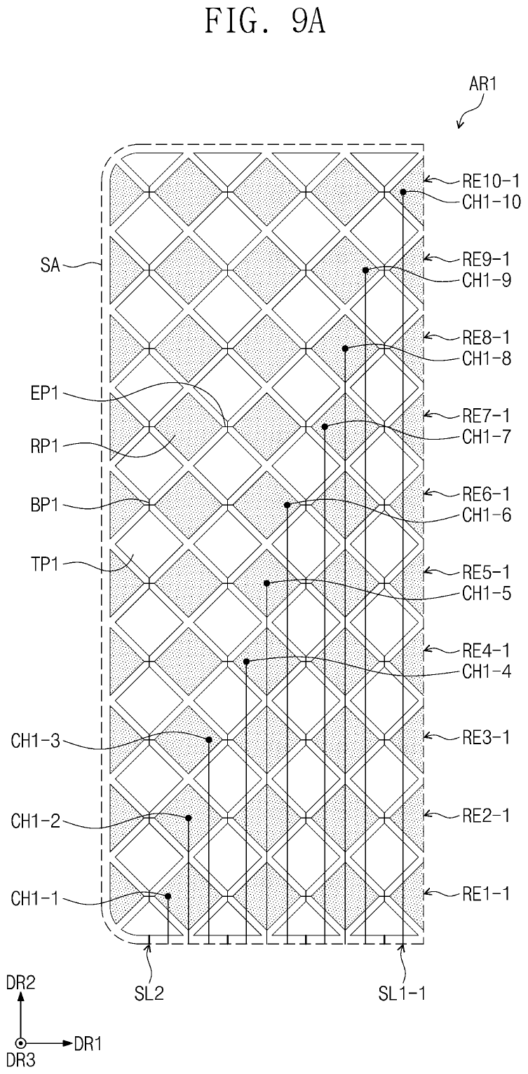

FIG. 7A is an enlarged plan view of an area RR of FIG. 6A. FIG. 7B is a cross-sectional view of the input sensor ISL according to an embodiment of the present disclosure. FIG. 8A is an enlarged plan view of an area TT of FIG. 6A. FIG. 8B is a cross-sectional view of the input sensor ISL according to an embodiment of the present disclosure.

Referring to FIG. 6A, the input sensor ISL may include a sensing area SA and a non-sensing area NSA defined adjacent to the sensing area SA. The sensing area SA and the non-sensing area NSA may respectively correspond to the active area AA and the peripheral area NAA of the display device DD shown in FIG. 2. The sensing area SA may be activated in response to electrical signals. Sensing controllers T-IC1 and T-IC2 may be disposed in the non-sensing area NSA.

The input sensor ISL may include first sensing electrodes RE and second sensing electrodes TE. The first sensing electrodes RE and the second sensing electrodes TE may be electrically insulated from each other and may cross each other.

Each of the first sensing electrodes RE may extend in the first direction DR1. The first sensing electrodes RE may be spaced apart from each other in the second direction DR2. As an example, the first sensing electrodes RE may include first to tenth row sensing electrodes RE1 to RE10. FIG. 6A shows ten first sensing electrodes RE, however, the number of the first sensing electrodes RE should not necessarily be limited to ten.

Each of the second sensing electrodes TE may extend in the second direction DR2. The second sensing electrodes TE may be spaced apart from each other in the first direction DR1. As an example, the second sensing electrodes TE may include first to sixteenth column sensing electrodes TE1 to TE16. FIG. 6A shows sixteen second sensing electrodes TE, however, the number of the second sensing electrodes TE should not necessarily be limited to sixteen.

In the present embodiment, the first sensing electrodes RE may have a length that is longer than the second sensing electrodes TE, and the number of the first sensing electrodes RE may be smaller than the number of the second sensing electrodes TE. However, the present disclosure should not necessarily be limited thereto or thereby.

The input sensor ISL may obtain information about the input TC (refer to FIG. 1) based on a variation in mutual capacitance between the first sensing electrodes RE and the second sensing electrodes TE.

The input sensor ISL may include first signal lines SL1 electrically connected to the first sensing electrodes RE and second signal lines SL2 electrically connected to the second sensing electrodes TE. At least one of the first signal lines SL1 may overlap the sensing area SA when viewed in the plan view. The second signal lines SL2 might not overlap the sensing area SA and may overlap the non-sensing area NSA.

The first sensing electrodes RE may be electrically connected to the sensing controllers T-IC1 and T-IC2 via the first signal lines SL1, and the second sensing electrodes TE may be electrically connected to the sensing controllers T-IC1 and T-IC2 via the second signal lines SL2.

The sensing controllers T-IC1 and T-IC2 may generate coordinate values of a position to which the input TC (refer to FIG. 1) is applied based on signals provided from the first and second signal lines SL1 and SL2.

Each of the first sensing electrodes RE and the second sensing electrodes TE shown in FIG. 6A may include a plurality of conductive lines crossing each other and may have a mesh shape with a plurality of openings.

FIG. 6B is an enlarged plan view of a first area AR1 of the input sensor ISL of FIG. 6A.

Referring to FIG. 6B, the first sensing electrodes RE and the second sensing electrodes TE may have a mesh shape, and as an example, the first sensing electrodes RE and the second sensing electrodes TE may be a metal mesh.

FIG. 6B shows a first-first signal line SL1-1 disposed in the first area AR1 among the first signal lines SL1 (refer to FIG. 6A). The first-first signal line SL1-1 may be disposed under the first sensing electrodes RE and the second sensing electrodes TE in the third direction DR3.

The first sensing electrodes RE and the second sensing electrodes TE shown in FIG. 6A may have a mesh shape in first, second, third, and fourth areas AR1, AR2, AR3, and AR4, which is the same as the mesh shape shown in FIG. 6B. In addition, first sensing electrodes RE and second sensing electrodes TE described with reference to FIGS. 7A to 13 may be a metal mesh that is the same as that shown in FIG. 6B.

Hereinafter, details related to the mesh shape will be described with reference to FIGS. 6A, 6B, 7A, and 7B.

Referring to FIGS. 6A, 6B, 7A, and 7B, the first sensing electrodes RE and the second sensing electrodes TE may have a structure of the mesh shape including a first mesh line ML1 and a second mesh line ML2. For example, the first mesh line ML1 may extend in a second diagonal direction DR5, and the second mesh line ML2 may extend in a first diagonal direction DR4. The first signal lines SL1 (refer to FIG. 6A) may have a width equal to or smaller than a width of the first mesh line ML1 and the second mesh line ML2. Accordingly, although the first signal lines SL1 (refer to FIG. 6A) are disposed under first and second sensing patterns RP1 and TP1, it is possible to maintain an excellent visibility of the sensing area SA.

The first mesh line ML1 of each of the first and second sensing patterns RP1 and TP1 may cross and may be provided integrally with the second mesh line ML2 of each of the first and second sensing patterns RP1 and TP1. The first mesh line ML1 and the second mesh line ML2 may define touch openings TOP each having a lozenge shape. The emission areas PXA (refer to FIG. 5) may be disposed in the touch openings TOP. For example, the light emitting element (refer to FIG. 5) may be disposed in the touch openings TOP. Since the emission areas PXA are disposed in the touch openings TOP, a light generated in the emission areas PXA may be emitted normally without being affected by the first and second sensing patterns RP1 and TP1.

The first sensing electrodes RE may include a plurality of first sensing patterns RP1 and a plurality of conductive patterns EP1, which are arranged in the first direction DR1. The conductive pattern EP1 may extend from the first sensing pattern RP1. The conductive pattern EP1 may be provided integrally with the first sensing pattern RP1. The conductive pattern EP1 may have the mesh shape.

The second sensing electrodes TE may include a plurality of second sensing patterns TP1 and a plurality of bridge patterns BP1, which are arranged in the second direction DR2. The bridge pattern BP1 may connect two second sensing patterns TP1 adjacent to each other. The bridge pattern BP1 may extend not to overlap the conductive pattern EP1 and may connect the second sensing patterns TP1. The bridge pattern BP1 may be electrically connected to the second sensing pattern TP1 via a plurality of contact holes TP-CH. The bridge pattern BP1 may extend toward the second sensing pattern TP1 via areas overlapping the first sensing pattern RP1.

According to an embodiment, the first sensing pattern RP1, the second sensing pattern TP1, and the conductive pattern EP1 may be disposed on the same layer and may be formed of the same material by being substantially simultaneously patterned. The bridge pattern BP1 may be disposed under the first sensing pattern RP1, the second sensing pattern TP1, and the conductive pattern EP1. The conductive patterns EP1 may be insulated from the bridge patterns BP1 and may be disposed between the second sensing patterns TP1.

The bridge pattern BP1 may include a first extension portion EX1 and a second extension portion EX2 having a shape that is symmetrical to the first extension portion EX1. The conductive pattern EP1 may be disposed between the first extension portion EX1 and the second extension portion EX2.

The first extension portion EX1 may connect the second sensing patterns TP1 via one first sensing pattern RP1 of two first sensing patterns RP1 shown in FIG. 7A. The second extension portion EX2 may connect the second sensing patterns TP1 via the other first sensing pattern RP1 of the two first sensing patterns RP1 shown in FIG. 7A. Since each of the first extension portion EX1 and the second extension portion EX2 connects two second sensing patterns TP1, the two second sensing patterns TP1 may be electrically connected normally to each other even though one of the first extension portion EX1 and the second extension portion EX2 is damaged.

Hereinafter, the two first sensing patterns RP1 may be defined as a left first sensing pattern RP1 and a right first sensing pattern RP1, respectively, according to a relative arrangement position. The two second sensing patterns TP1 may be defined as an upper second sensing pattern TP1 and a lower second sensing pattern TP1, respectively, according to a relative arrangement position.

Portions of the first and second extension portions EX1 and EX2, which are adjacent to one sides of the first and second extension portions EX1 and EX2, may be electrically connected to the lower second sensing pattern TP1 via the contact holes TP-CH. Portions of the first and second extension portions EX1 and EX2, which are adjacent to the other sides of the first and second extension portions EX1 and EX2, may be electrically connected to the upper second sensing pattern TP1 via the contact holes TP-CH.

The first extension portion EX1 may include a first sub-extension portion EX1_1 and a second sub-extension portion EX1_2, which extend in the first diagonal direction DR4, and a third sub-extension portion EX1_3 and a fourth sub-extension portion EX1_4, which extend in the second diagonal direction DR5. The first extension portion EX1 may further include a first sub-conductive pattern SCP1 extending in the second diagonal direction DR5 and a second sub-conductive pattern SCP2 extending in the first diagonal direction DR4.

Portions of the first and second sub-extension portions EX1_1 and EX1_2, which are adjacent to one sides of the first and second sub-extension portions EX1_1 and EX1_2, may be electrically connected to the lower second sensing pattern TP1 via the contact holes TP-CH. Portions of the third and fourth sub-extension portions EX1_3 and EX1_4, which are adjacent to one sides of the third and fourth sub-extension portions EX1_3 and EX1_4, may be electrically connected to the upper second sensing pattern TP1 via the contact holes TP-CH.

The first sub-extension portion EX1_1 may extend from the third sub-extension portion EX1_3, and the second sub-extension portion EX1_2 may extend from the fourth sub-extension portion EX1_4. The first sub-conductive pattern SCP1 may connect the first sub-extension portion EX1_1, the second sub-extension portion EX1_2, and the fourth sub-extension portion EX1_4. The second sub-conductive pattern SCP2 may connect the second sub-extension portion EX1_2, the third sub-extension portion EX1_3, and the fourth sub-extension portion EX1_4. The first sub-extension portion EX1_1, the second sub-extension portion EX1_2, the third sub-extension portion EX1_3, the fourth sub-extension portion EX1_4, the first sub-conductive pattern SCP1, and the second sub-conductive pattern SCP2 may be provided integrally with each other.

The first and second mesh lines ML1 and ML2 might not be disposed in portions overlapping portions of the first and second sub-extension portions EX1_1 and EX1_2, portions of the third and fourth sub-extension portions EX1_3 and EX1_4, the first sub-conductive pattern SCP1, and the second sub-conductive pattern SCP2.

The second extension portion EX2 may include a fifth sub-extension portion EX2_1 and a sixth sub-extension portion EX2_2, which extend in the second diagonal direction DR5, and a seventh sub-extension portion EX2_3 and an eighth sub-extension portion EX2_4, which extend in the first diagonal direction DR4. The second extension portion EX2 may further include a third sub-conductive pattern SCP3 extending in the first diagonal direction DR4 and a fourth sub-conductive pattern SCP4 extending in the second diagonal direction DR5.

The left first sensing pattern RP1 may have a structure that is symmetrical to that of the right first sensing pattern RP1, and the second extension portion EX2 may have a structure that is symmetrical to that of the first extension portion EX1. For example, the descriptions of the first, second, third, and fourth sub-extension portions EX1_1, EX1_2, EX1_3, and EX1_4 may be applied to the fifth, sixth, seventh, and eighth sub-extension portions EX2_1, EX2_2, EX2_3, and EX2_4, and the descriptions of the first and second sub-conductive patterns SCP1 and SCP2 may be applied to the third and fourth sub-conductive patterns SCP3 and SCP4.

Referring to FIGS. 7A and 7B, the bridge pattern BP1 may be disposed on the base insulating layer 201. The bridge pattern BP1 may be covered by the first sensor insulating layer 203.

The first sensing pattern RP1 and the second sensing pattern TP1 may be disposed on the first sensor insulating layer 203. The first sensing pattern RP1 and the second sensing pattern TP1 may be covered by the second sensor insulating layer 205.

The second sensing pattern TP1 may be electrically connected to the bridge pattern BP1 via the contact holes TP-CH defined through the first sensor insulating layer 203.

Referring to FIG. 6A again, the input sensor ISL may include two or more areas distinguished from each other in the first direction DR1. For example, the sensing area SA included in the input sensor ISL may include two or more areas distinguished from each other in the first direction DR1. The sensing area SA may be divided into plural areas in a direction of extension of a long side. However, the present disclosure should not necessarily be limited thereto or thereby.

FIG. 6A shows a structure in which the sensing area SA includes the first area AR1, the second area AR2, the third area AR3, and the fourth area AR4, which are distinguished from each other in the first direction DR1, however, the present disclosure should not necessarily be limited thereto or thereby. According to an embodiment, the sensing area SA may include two, three, five, or more areas distinguished from each other in the first direction DR1.

The second sensing electrodes TE1 to TE16 may be divided into groups and the groups of the second sensing electrodes TE1 to TE16 may be respectively arranged in the first, second, third, and fourth areas AR1, AR2, AR3, and AR4, but each of the first sensing electrodes RE1 to RE10 may be arranged to overlap the first, second, third, and fourth areas AR1, AR2, AR3, and AR4.

Each of the first sensing electrodes RE1 to RE10 may include a first portion PT1 overlapping the first area AR1 in a plan view, a second portion PT2 overlapping the second area AR2 in a plan view, a third portion PT3 overlapping the third area AR3 in a plan view, and a fourth portion PT4 overlapping the fourth area AR4 in a plan view. The first portion PT1 and the fourth portion PT4 may be disposed at one end and the other end of the sensing area SA, and the second portion PT2 and the third portion PT3 may be disposed inside the sensing area SA. In FIGS. 6A to 10, the one end and the other end of the sensing area SA may indicate one end and the other end substantially extending in the second direction DR2. In addition, one end and the other end of the first, second, third, and fourth portions PT1, PT2, PT3, and PT4 may indicate one end and the other end substantially extending in the second direction DR2.

The first, second, third, and fourth portions PT1, PT2, PT3, and PT4 may be electrically connected to each other. FIG. 6A shows a structure in which the first, second, third, and fourth portions PT1, PT2, PT3, and PT4 are provided integrally with each other, however, the present disclosure should not necessarily be limited thereto or thereby. According to an embodiment, the first, second, third, and fourth portions PT1, PT2, PT3, and PT4 may be electrically connected to each other via the bridge pattern BP1.

Each of the first sensing electrodes RE1 to RE10 may be electrically connected to two or more first signal lines SL1. As an example, each of the first, second, third, and fourth portions PT1, PT2, PT3, and PT4 may be electrically connected to the first signal line SL1. For example, the first row sensing electrode RE1 may include the first, second, third, and fourth portions PT1, PT2, PT3, and PT4 respectively overlapping the first, second, third, and fourth areas AR1, AR2, AR3, and AR4 in a plan view. The first row sensing electrode RE1 may be electrically connected to the first-first signal line SL1-1, a first-second signal line SL1-2, a first-third signal line SL1-3, and a first-fourth signal line SL1-4, which are portions of the first signal lines SL1. The first-first, first-second, first-third, and first-fourth signal lines SL1-1, SL1-2, SL1-3, and SL1-4 may be respectively electrically connected to the first, second, third, and fourth portions PT1, PT2, PT3, and PT4 of the first row sensing electrode RE1.

At least one of the first-first, first-second, first-third, and first-fourth signal lines SL1-1, SL1-2, SL1-3, and SL1-4 may overlap the sensing area SA. For example, at least one of the first-first, first-second, first-third, and first-fourth signal lines SL1-1, SL1-2, SL1-3, and SL1-4 may overlap the first row sensing electrode RE1 in a plan view. FIG. 6A shows a structure in which all the first-first, first-second, first-third, and first-fourth signal lines SL1-1, SL1-2, SL1-3, and SL1-4 overlap the first row sensing electrode RE1 in a plan view as a representative example.

The first-first, first-second, first-third, and first-fourth signal lines SL1-1, SL1-2, SL1-3, and SL1-4 may extend in the second direction DR2 in the sensing area SA toward the non-sensing area NSA. The first-first, first-second, first-third, and first-fourth signal lines SL1-1, SL1-2, SL1-3, and SL1-4 may be electrically connected to the sensing controllers T-IC1 and T-IC2 disposed in the non-sensing area NSA. For example, the first-first and first-second signal lines SL1-1, SL1-2 may be electrically connected to a first sensing controller T-IC1, and the first-third and first-fourth signal lines SL1-3 and SL1-4 may be electrically connected to a second sensing controller T-IC2.

For example, when the first row sensing electrode RE1 is divided into plural areas, the first signal lines SL1-1, SL1-2, SL1-3, and SL1-4 may provide signals generated in the plural areas to the sensing controllers T-IC1 and T-IC2.

The structure of the first signal lines SL1 described with reference to the first row sensing electrode RE1 may be applied to the second to tenth row sensing electrodes RE2 to RE10. Each of the second to tenth row sensing electrodes RE2 to RE10 may include the first, second, third, and fourth portions PT1, PT2, PT3, and PT4 and the first-first, first-second, first-third, and first-fourth signal lines SL1-1, SL1-2, SL1-3, and SL1-4 respectively electrically connected to the first, second, third, and fourth portions PT1, PT2, PT3, and PT4.

Each of the first-first, first-second, first-third, and first-fourth signal lines SL1-1, SL1-2, SL1-3, and SL1-4 may be electrically connected to the first sensing pattern RP1 of the first row sensing electrode RE1. The first signal line SL1 may be electrically connected to the first sensing pattern RP1 via a contact hole CH1.

Referring to FIGS. 6A, 8A, and 8B, the contact hole CH1 may be formed through the first sensing pattern RP1 in a plan view. The position of the contact hole CH1 shown in FIG. 8A is merely an example, and the present disclosure should not necessarily be limited thereto or thereby. The position of the contact hole CH1 in a plan view may be determined by taking into account a coupling between the first signal line SL1 electrically connected to the first sensing pattern RP1 and the second sensing pattern TP1.

For example, the first signal line SL1 electrically connected to the first sensing pattern RP1 may be disposed in a way to minimize the overlap between the first signal line SL1 and the second sensing pattern TP1 in a plan view. As an example, the first signal line SL1 may overlap the first sensing pattern RP1 rather than the second sensing pattern TP1 in a plan view. Accordingly, the coupling between the first signal line SL1 electrically connected to the first sensing pattern RP1 and the second sensing pattern TP1 may be reduced, and a reliability of the input sensor may be increased.

FIG. 8B is a cross-sectional view taken along a line III-III′ shown in FIG. 8A. Referring to FIG. 8B, the first and second sensing patterns RP1 and TP1 may be disposed on the same layer, for example, on the first sensor insulating layer 203. The first-first signal line SL1-1 may be disposed on a different layer from the first sensor insulating layer 203, for example, on the base insulating layer 201.

As an example, the first and second sensing patterns RP1 and TP1 may be included in the second conductive pattern 204 shown in FIG. 5, and the first signal line SL1 may be included in the first conductive pattern 202 shown in FIG. 5.

As an example, the first and second sensing patterns RP1 and TP1 and the first signal line SL1 may include a metal layer.

Referring to FIGS. 7B and 8B, the first and second sensing patterns RP1 and TP1 and the conductive patterns EP1 may be disposed on the same layer, for example, on the first sensor insulating layer 203. The first-first signal line SL1-1 and the bridge pattern BP1 may be disposed on a different layer from the first sensor insulating layer 203, for example, on the base insulating layer 201.

As an example, the first and second sensing patterns RP1 and TP1 and the conductive patterns EP1 may be included in the second conductive pattern 204 shown in FIG. 5, and the bridge patterns BP1 and the first-first signal line SL1-1 may be included in the first conductive pattern 202 shown in FIG. 5, however, the present disclosure should not necessarily be limited thereto or thereby. According to an embodiment, the first and second sensing patterns RP1 and TP1 and the conductive patterns EP1 may be included in the first conductive pattern 202 shown in FIG. 5, and the bridge patterns BP1 and the first signal line SL1-1 may be included in the second conductive pattern 204 shown in FIG. 5.

As described with reference to FIGS. 6A to 8B, the first signal lines SL1 including the first-first, first-second, first-third, and first-fourth signal lines SL1-1, SL1-2, SL1-3, and SL1-4 may be electrically connected to the first sensing patterns RP1 via the contact hole CH1 and may overlap the first sensing electrodes RE in a plan view. For example, the first signal lines SL1 may be disposed in the sensing area SA. Accordingly, the first signal lines SL1 may be electrically connected to the second and third portions PT2 and PT3 disposed between the first and fourth portions PT1 and PT4 as well as the first and fourth portions PT1 and PT4 whose one end is adjacent to the non-sensing area NSA.

In the drawings, the first-first signal lines SL1-1 are illustrated as being disposed only between the sensing controllers T-IC1 and T-IC2 and a corresponding contact hole CH1, however, each of the first-first signal lines SL1-1 may extend from the sensing controllers T-IC1 and T-IC2 to the tenth row sensing electrode RE10. In addition, the contact hole CH1 may be formed at a desired position, and thus, the first-first signal lines SL1-1 may be electrically connected to corresponding first to tenth row sensing electrodes RE1 to RE10.

In the present disclosure, when the sensing area SA of the input sensor ISL lengthens in the first direction DR1, each of the first sensing electrodes RE extending in the first direction DR1 may be divided into plural areas, and each divided area may be electrically connected to the signal line. Accordingly, it is possible to prevent an increase in load capacitance according to the length of the sensing electrode and to maintain an excellent sensing performance.

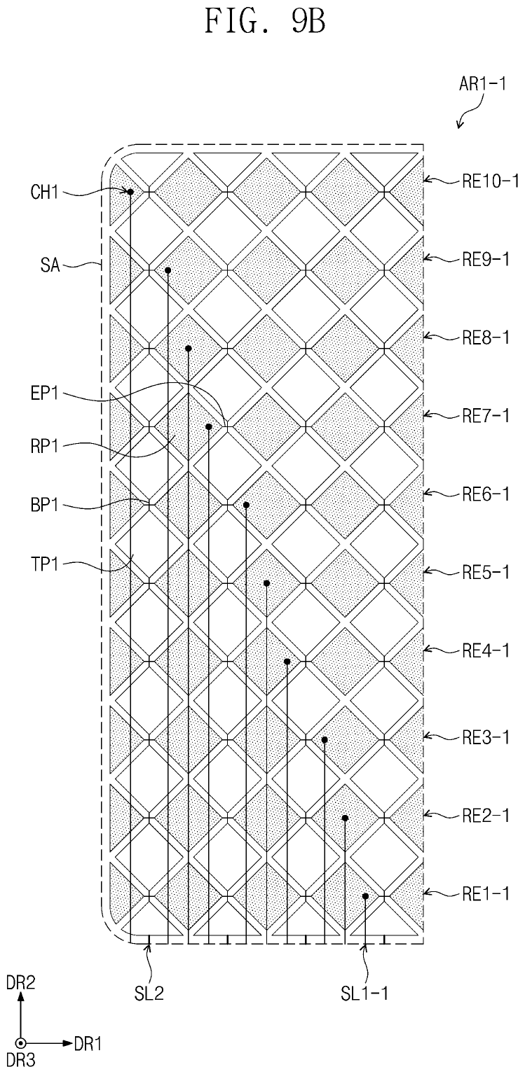

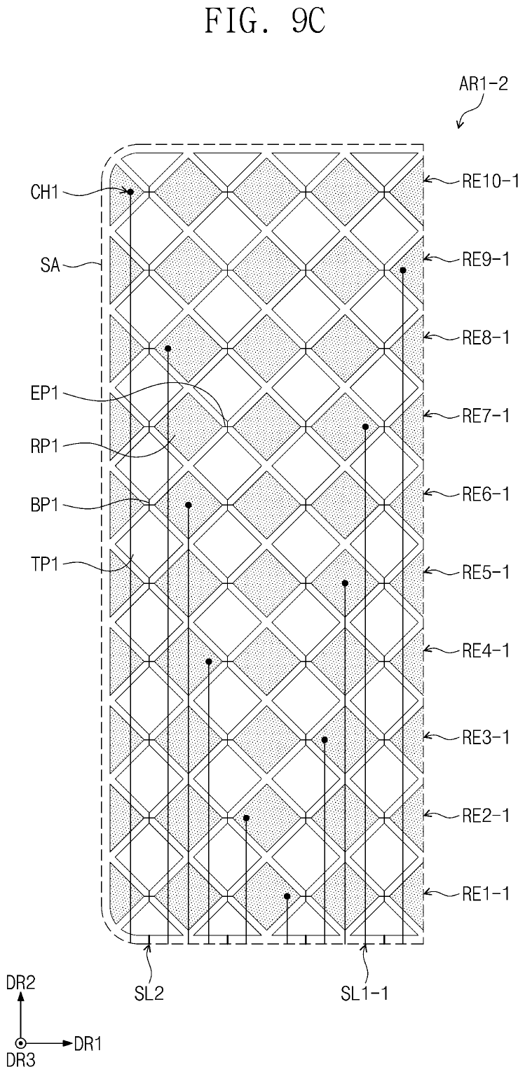

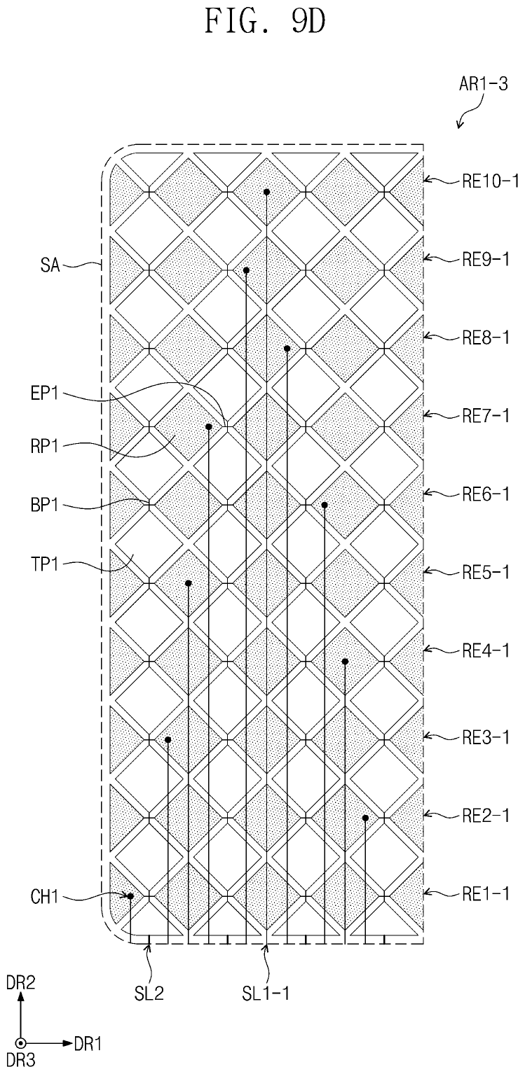

FIG. 9A is an enlarged plan view of the first area AR1 of FIG. 6A. FIG. 9B is an enlarged plan view of a first area AR1-1 according to an embodiment of the present disclosure. FIG. 9C is an enlarged plan view of a first area AR1-2 according to an embodiment of the present disclosure. FIG. 9D is an enlarged plan view of a first area AR1-3 according to an embodiment of the present disclosure. FIGS. 9B to 9D show embodiments of the first area AR1 shown in FIG. 6A.

FIGS. 9A to 9D are enlarged views of the first portions PT1 (hereinafter, referred to as RE1-1 to RE10-1) of the first to tenth row sensing electrodes RE1 to RE10 shown in FIG. 6A.

Referring to FIG. 9A, the first portions RE1-1 to RE10-1 may be electrically connected to the first-first signal lines SL1-1 in a one-to-one correspondence. The first-first signal lines SL1-1 may be electrically connected to the first sensing patterns RP1 respectively included in the first portions RE1-1 to RE10-1 via contact holes CH1-1 to CH1-10.

The first-first signal lines SL1-1 may be arranged spaced apart from each other in the first direction DR1 and might not overlap each other. Each of the first-first signal lines SL1-1 may extend from a corresponding contact hole among the contact holes CH1-1 to CH1-10 to a direction opposite to the second direction DR2. A distance in the first direction DR1 between the first-first signal lines SL1-1 may be determined depending on the positions of the contact holes CH1-1 to CH1-10. The positions of the contact holes CH1-1 to CH1-10 in the first sensing pattern RP1 may be determined in a way to minimize a coupling value between the first signal lines SL1-1 and the second sensing pattern TP1

For example, the contact holes CH1-1 to CH1-10 may be arranged in a way to minimize the overlap between the first signal lines SL1-1 and the second sensing pattern TP1 in a plan view. In a case where the contact holes CH1-1 to CH1-10 are disposed at a center of the first sensing pattern RP1, the first signal line SL1 might not overlap the second sensing pattern TP1 in a plan view when extending in the second direction DR2. For example, since the first signal line SL1 overlaps only the first sensing pattern RP1 in a plan view, the coupling between the first signal line SL1 and the second sensing pattern TP1 may be reduced, and the reliability of the input sensor may be increased. In the present disclosure, the center of the first sensing pattern RP1 may mean a point at which a midline of the first sensing pattern RP1 in the first direction DR1 intersects with a midline of the first sensing pattern RP1 in the second direction DR2.

However, in consideration of the number of the first-first signal lines SL1-1 and the distance between the first-first signal lines SL1-1, some of the contact holes CH1-1 to CH1-10 may be disposed not to overlap the second sensing pattern TP1, and the other of the contact holes CH1-1 to CH1-10 may overlap the second sensing pattern TP1 and the first sensing pattern RP1.

As an example, a first-first contact hole CH1-1, a first-third contact hole CH1-3, a first-fourth contact hole CH1-4, a first-sixth contact hole CH1-6, a first-seventh contact hole CH1-7, a first-ninth contact hole CH1-9, and a first-tenth contact hole CH1-10 may be formed at a left or right side in the first sensing pattern RP1. Accordingly, the first-first signal lines SL1-1 electrically connected to the first-first contact hole CH1-1, the first-third contact hole CH1-3, the first-fourth contact hole CH1-4, the first-sixth contact hole CH1-6, the first-seventh contact hole CH1-7, the first-ninth contact hole CH1-9, and the first-tenth contact hole CH1-10 may overlap a portion of the second sensing pattern TP1 and a portion of the first sensing pattern RP1 in a plan view.

As an example, each of a first-second contact hole CH1-2, a first-fifth contact hole CH-5, and a first-eighth contact hole CH8 may be formed at the center in the first sensing pattern RP1. Accordingly, the first signal lines SL1-1 electrically connected to the first-second contact hole CH1-2, the first-fifth contact hole CH-5, and the first-eighth contact hole CH8 might not overlap the second sensing pattern TP1 and may overlap only the first sensing pattern RP1 in a plan view.

The structure shown in FIG. 9A is merely an example, and the first-first contact hole CH1-1, the first-third contact hole CH1-3, the first-fourth contact hole CH1-4, the first-sixth contact hole CH1-6, the first-seventh contact hole CH1-7, the first-ninth contact hole CH1-9, and the first-tenth contact hole CH1-10 may be disposed closer to the center in the first sensing pattern RP1 by taking into account the distance between the first-first signal lines SL1-1.

As described above, the positions of the contact holes CH1-1 to CH1-10 in the first sensing pattern RP1 may be determined by taking into account the coupling value between the second sensing pattern TP1 and the first-first signal lines SL1-1, the number of the first sensing electrodes RE1-1 to RE10-1, and the number of the first-first signal lines SL1-1.

In the drawings to be described later, the first signal line SL1 may overlap the first sensing pattern RP1 more than the second sensing pattern TP1 in a plan view. Accordingly, the coupling between the first signal line SL1 electrically connected to the first sensing pattern RP1 and the second sensing pattern TP1 may be reduced, and the reliability of the input sensor may be increased.

FIG. 9A shows a structure in which the positions of the contact holes CH1-1 to CH1-10 become farther away in the second direction DR2 from the sensing controllers T-IC1 (refer to FIG. 6A) as it goes in the first direction DR1. However, the arrangement of the contact holes CH1-1 to CH1-10 and the first-first signal lines SL1-1 should not necessarily be limited thereto or thereby. Referring to FIG. 9B, the positions of the contact hole CH1 become farther away in the second direction DR2 from the sensing controllers T-IC1(refer to FIG. 6a) as it goes in a direction opposite to the first direction DR1. According to embodiments, the positions of the contact holes CH1 may be changed in various ways as shown in FIGS. 9C and 9D and should not necessarily be particularly limited thereto.

The positions of the contact holes CH1 and the first-first signal lines SL1-1 applied to the first area AR1 may be equally applied to the second, third, and fourth areas AR2, AR3, and AR4. As the arrangement of the first-first to first-fourth signal lines SL1-1 to SL1-4 is uniform in the first, second, third, and fourth areas AR1, AR2, AR3, and AR4, the coupling values generated in the first, second, third, and fourth areas AR1, AR2, AR3, and AR4 may be uniformly controlled.

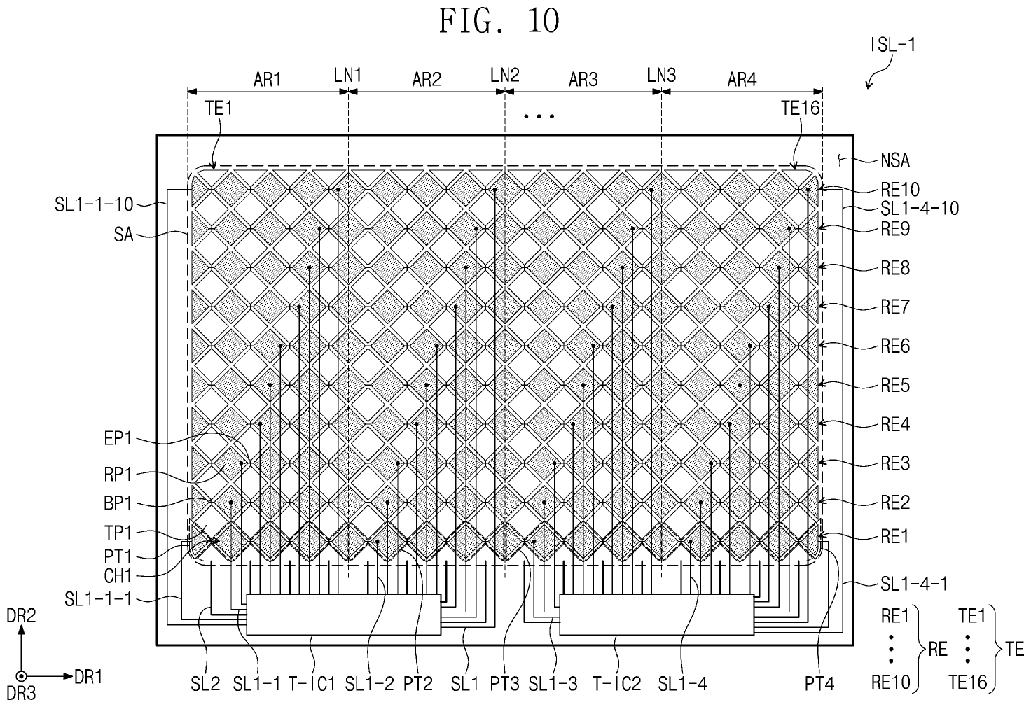

FIG. 10 is a plan view of an input sensor ISL-1 according to an embodiment of the present disclosure.

FIG. 10 shows a structure in which a portion of first signal lines SL1 is disposed in a non-sensing area NSA. One end of each of a first portion PT1 and a fourth portion PT4, which are included in each of first sensing electrodes RE1 to RE10, may be adjacent to the non-sensing area NSA. Accordingly, the portion of the first signal lines SL1 electrically connected to the first portion PT1 and the fourth portion PT4 may be disposed in the non-sensing area NSA. As an example, a first-first signal line SL1-1-1 electrically connected to the first portion PT1 of a first row sensing electrode RE1 and a fourth-first signal line SL1-4-1 electrically connected to the fourth portion PT4 of the first row sensing electrode RE1 may be disposed in the non-sensing area NSA. In addition, a first-first signal line SL1-1-10 electrically connected to the first portion PT1 of a tenth row sensing electrode RE10 and a fourth-first signal line SL1-4-10 electrically connected to the fourth portion PT4 of the tenth row sensing electrode RE10 may be disposed in the non-sensing area NSA.

The first signal lines SL1 electrically connected to second and third portions PT2 and PT3 disposed between the first and fourth portions PT1 and PT4 may overlap the sensing area SA.

Referring to FIGS. 6A to 10, in the input sensors ISL and ISL-1 of the display devices DD, at least one of the first signal lines SL1 may overlap the first sensing electrodes RE in a plan view. Accordingly, although the length and the size of the input sensors ISL and ISL-1 increase in one direction, the input sensors ISL and ISL-1 may be divided into plural areas in the one direction and may receive signals for each areas.

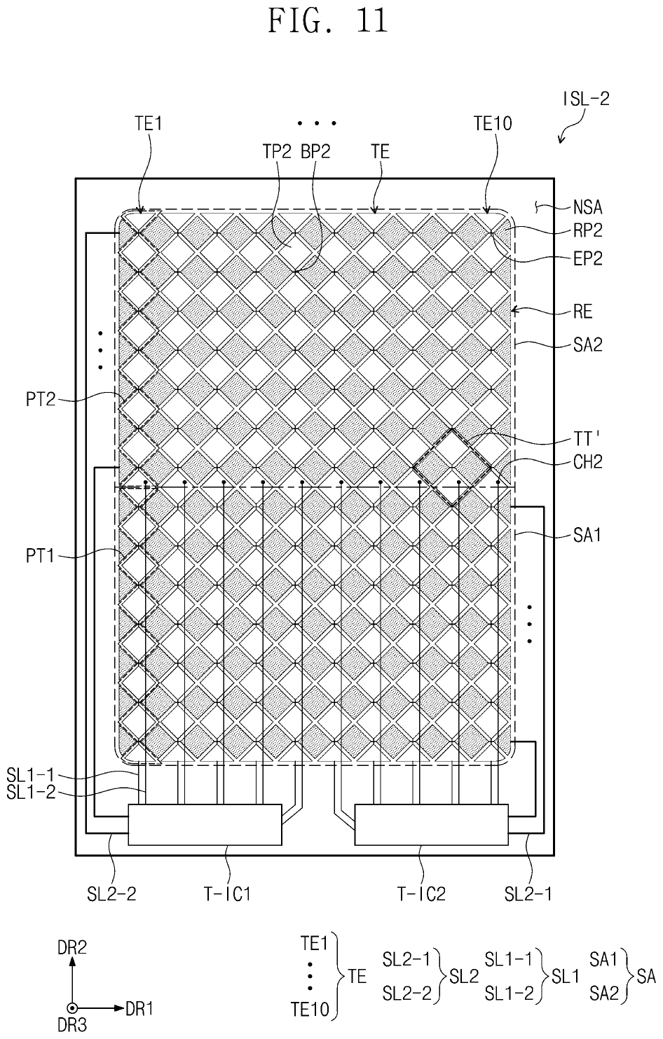

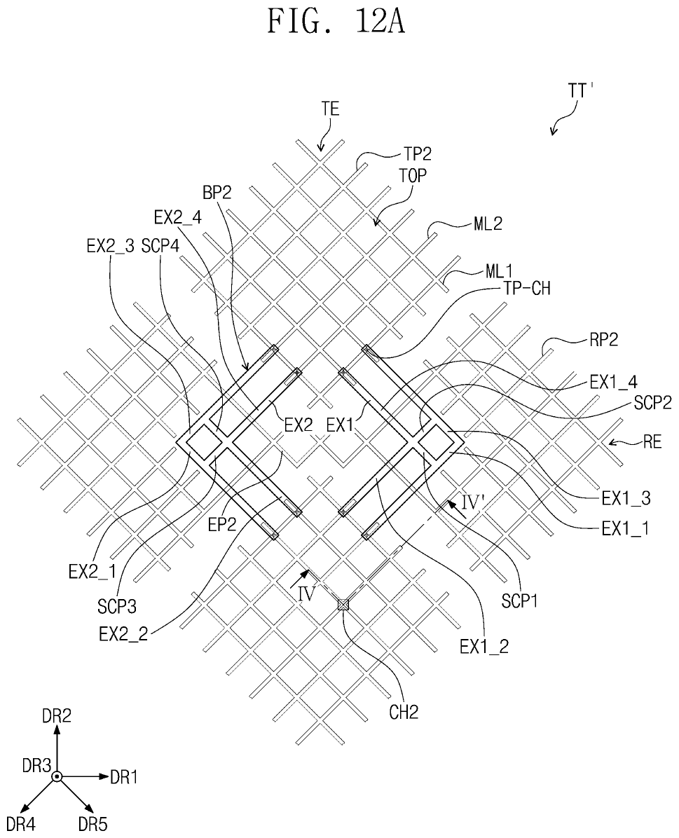

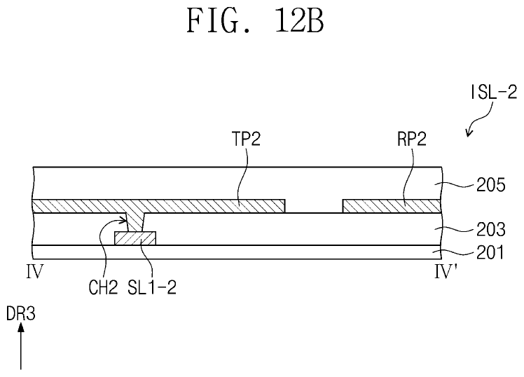

FIG. 11 is a plan view of an input sensor ISL-2 according to an embodiment of the present disclosure. FIG. 12A is an enlarged plan view of an area TT′ of FIG. 11. FIG. 12B is a cross-sectional view of the input sensor ISL-2 according to an embodiment of the present disclosure.

Referring to FIGS. 6A to 10, the sensing area SA has been described as including the first sensing electrodes RE and the second sensing electrodes TE. In the descriptions below with reference to FIGS. 11 to 13, a sensing area SA is described as including first sensing electrodes TE and second sensing electrodes RE. Referring to FIG. 11, the sensing area SA may include a long side extended in the second direction DR2 and a short side extended in the first direction DR1. Sensing controllers T-IC1 and T-IC2 may be disposed adjacent to a lower portion of the sensing area SA when viewed in the second direction DR2.

The sensing area SA may include a plurality of areas distinguished from each other in the second direction DR2 that is a direction of extension of a long side. As an example, the sensing area SA may include a first sensing area SA1 and a second sensing area SA2. In the second direction DR2, the first sensing area SA1 may be disposed between the sensing controllers T-IC1 and T-IC2 and the second sensing area SA2. FIG. 11 shows the structure in which the sensing area SA includes two areas distinguished from each other in the second direction DR2, however, the present disclosure should not necessarily be limited thereto or thereby. According to an embodiment, the sensing area SA may include three or more areas distinguished from each other in the second direction DR2.

Each of the first sensing electrodes TE may extend in the second direction DR2, and the first sensing electrodes TE may be spaced apart from each other in the first direction DR1. Each of the first sensing electrodes TE may include a plurality of first sensing patterns TP2 and a plurality of bridge patterns BP2, which are arranged in the second direction DR2. At least one bridge pattern BP2 may be electrically connected to two first sensing patterns TP2 adjacent to each other.

Each of the second sensing electrodes RE may extend in the first direction DR1, and the second sensing electrodes RE may be spaced apart from each other in the second direction DR2. Each of the second sensing electrodes RE may include a plurality of second sensing patterns RP2 and a plurality of extension patterns EP2, which are arranged in the first direction DR1. At least one extension pattern EP2 may extend from two second sensing patterns RP2 adjacent to each other. The extension pattern EP2 may be formed integrally with two second sensing patterns RP2 adjacent to each other. The extension patterns EP2 may be insulated from the bridge patterns BP2 and may extend to cross the bridge patterns BP2.

The first sensing electrodes TE may be electrically connected to the sensing controllers T-IC1 and T-IC2 via first signal lines SL1, and the second sensing electrodes RE may be electrically connected to the sensing controllers T-IC1 and T-IC2 via second signal lines SL2.

Among the second sensing electrodes RE, the second sensing electrodes RE overlapping the first sensing area SA1 may be electrically connected to a second sensing controller T-IC2 via second-first signal lines SL2-1. Among the second sensing electrodes RE, the second sensing electrodes RE overlapping the second sensing area SA2 may be electrically connected to a first sensing controller T-IC1 via second-second signal lines SL2-2. According to an embodiment, the second signal lines SL2 may overlap the non-sensing area NSA.

According to an embodiment, at least a portion of the first signal lines SL1 may overlap the sensing area SAL

Each of the first sensing electrodes TE may include a first portion PT1 overlapping the first sensing area SA1 and a second portion PT2 overlapping the second sensing area SA2.

The first portion PT1 may be electrically connected to a first-first signal line SL1-1, and the second portion PT2 may be electrically connected to a first-second signal line SL1-2. For example, each of the first sensing electrodes TE may be electrically connected to two first signal lines SL1.

The first-first signal line SL1-1 may connect an end of the first portion PT1 and the sensing controllers T-IC1 and T-IC2. For example, the first-first signal line SL1-1 may be electrically connected to the first sensing pattern TP2 adjacent to the sensing controllers T-IC1 and T-IC2 and disposed at the end of the first portion PT1. In FIGS. 11 to 13, one end of each of the first portion PT1 and the second portion PT2 may indicate one end extending in the first direction DR1. The first-first signal line SL1-1 may be disposed in the non-sensing area NSA.

The first-second signal line SL1-2 may connect the second portion PT2 and the sensing controllers T-IC1 and T-IC2. For example, the first-second signal line SL1-2 may be electrically connected to the first sensing patterns TP2 disposed at the one end of the second portion PT2 and adjacent to the other end of the first portion PT1. The first-second signal line SL1-2 may overlap the first sensing patterns TP2 in a plan view and may be electrically connected to the first sensing patterns TP2 via a contact hole CH2.

Referring to FIGS. 11, 12A, and 12B, the contact hole CH2 may be formed through the first sensing pattern TP2 in a plan view. A position of the contact hole CH2 in the first sensing pattern TP2 should not necessarily be limited to the position shown in FIGS. 11, 12A, and 12B and may be adjusted as needed. The position of the contact hole CH2 in a plan view may be determined by taking into account a coupling between the first-second signal line SL1-2 and the second sensing pattern RP2.

FIG. 12B is a cross-sectional view taken along a line IV-IV′ shown in FIG. 12A. Referring to FIG. 12B, the first and second sensing patterns TP2 and RP2 may be disposed on the same layer, for example, a first sensor insulating layer 203. The first-second signal line SL1-2 may be disposed on a different layer from the first sensor insulating layer 203, for example, a base insulating layer 201.

As an example, the first and second sensing patterns TP2 and RP2 may be included in the second conductive pattern 204 shown in FIG. 5, and the first-second signal line SL1-2 may be included in the first conductive pattern 202 shown in FIG. 5.

As an example, the first and second sensing patterns TP2 and RP2 and the first-second signal line SL1-2 may include a metal layer.

Referring to FIG. 11 again, the contact holes CH2 formed through the first sensing electrodes TE may be disposed adjacent to the other end of the first portion PT1. Accordingly, a distance between the sensing controllers T-IC1 and T-IC2 and the contact holes CH2 may be reduced, and thus, a load on the first-second signal line SL1-2 may be reduced.

However, the position of the contact holes CH2 should not necessarily be limited thereto or thereby.

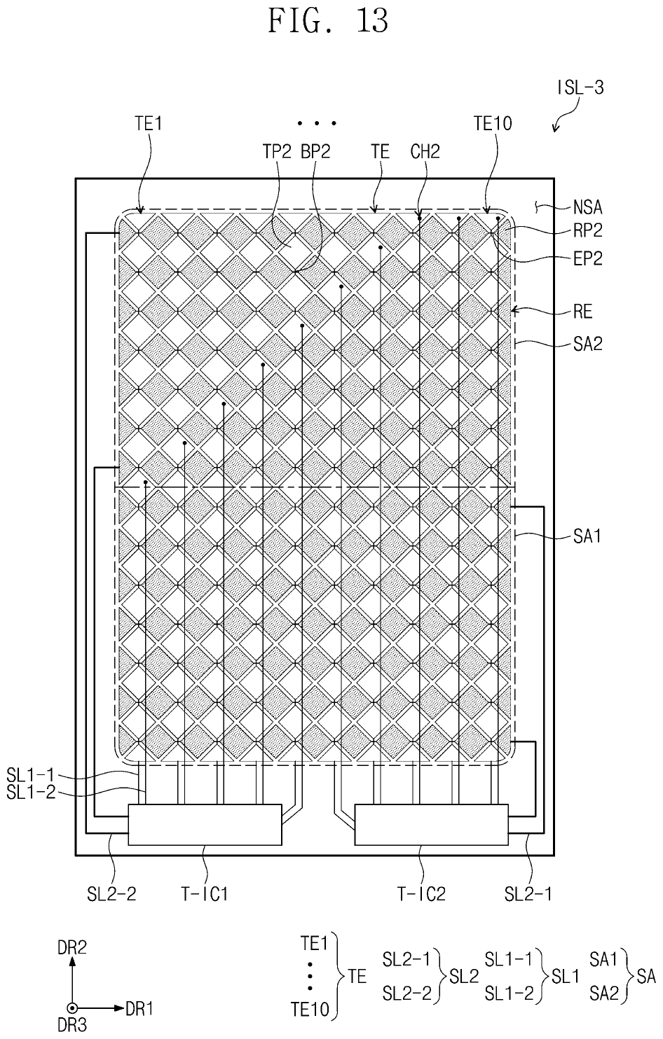

FIG. 13 is a plan view of an input sensor ISL-3 according to an embodiment of the present disclosure.

Referring to FIG. 13, positions of contact holes CH2 may be farther away from sensing controllers T-IC1 and T-IC2 in the second direction DR2 within a second sensing area SA2 as it goes to the first direction DR1. The positions of the contact holes CH2 may be closer to the sensing controllers T-IC1 and T-IC2 in the direction opposite to the second direction DR2 as it goes to the first direction DR1.

According to the display device DD of the present disclosure, although the length and the size of the input sensor ISL increase in one direction, the sensing area SA may be divided into plural areas in the one direction, and the signal line may be electrically connected to each of the divided areas to overlap the sensing area SA. Thus, the increase in load capacity due to the increase of the sensing area SA may be prevented, and the excellent sensing performance may be provided.

Although the embodiments of the present disclosure have been described, it is understood that the present disclosure should not necessarily be limited to these embodiments but various changes and modifications can be made by one ordinary skilled in the art within the spirit and scope of the present disclosure.

What is claimed is:

1. A display device, comprising:
a display panel comprising a long side extending in a first direction and a short side extending in a second direction crossing the first direction; and
an input sensor disposed on the display panel, the input sensor comprising:
first sensing electrodes each extending in the first direction along the long side of the display panel;
second sensing electrodes each extending in the second direction along the short side of the display panel;
first signal lines electrically connected to the first sensing electrodes; and
second signal lines electrically connected to the second sensing electrodes,
wherein each of the first sensing electrodes is electrically connected to two or more first signal lines among the first signal lines, and
wherein at least one of the two or more first signal lines overlaps the first sensing electrodes.

2. The display device of claim 1, wherein the input sensor comprises a first area, a second area, and a third area, which are each distinguished from each other in the first direction,
wherein each of the first sensing electrodes comprises a first portion overlapping the first area, a second portion overlapping the second area, and a third portion overlapping the third area, and
wherein the two or more first signal lines comprise a first-first signal line electrically connected to the first portion, a first-second signal line electrically connected to the second portion, and a first-third signal line electrically connected to the third portion.

3. The display device of claim 2, wherein the first area is disposed at one end of the input sensor, and each of the first-first, first-second, and first-third signal lines overlaps the first sensing electrodes.

4. The display device of claim 2, wherein the first area is disposed at one end of the input sensor, the first-first signal line does not overlap the first sensing electrodes, and each of the first-second signal line and the first-third signal line overlaps the first sensing electrodes.

5. The display device of claim 2, wherein at least one of the two or more first signal lines extends in the second direction.

6. The display device of claim 2, wherein each of the first sensing electrodes comprises a plurality of first sensing patterns arranged in the first direction and a plurality of extension patterns extending from the plurality of first sensing patterns, and
wherein each of the second sensing electrodes comprises a plurality of second sensing patterns arranged in the second direction and a plurality of bridge patterns electrically connecting the plurality of second sensing patterns to one another.

7. The display device of claim 6, wherein the first signal lines are electrically connected to the first sensing patterns.

8. The display device of claim 7, wherein positions at which the first signal lines are electrically connected to the first sensing patterns are the same as each other in the first, second, and third areas.

9. The display device of claim 2, wherein the first sensing electrodes comprise a first row sensing electrode, a second row sensing electrode, and a third row sensing electrode, which are spaced apart from each other in the second direction, and
wherein the first-first signal lines respectively electrically connected to the first, second, and third row sensing electrodes do not overlap each other.

10. The display device of claim 2, wherein the input sensor further comprises a sensing controller disposed adjacent to a lower side of the first sensing electrodes and the second sensing electrodes in the second direction.

11. The display device of claim 1, wherein the input sensor comprises a first area and a second area distinguished from the first area in the first direction,
wherein each of the first sensing electrodes comprises a first portion overlapping the first area and a second portion overlapping the second area, and
wherein the two or more first signal lines comprise a first-first signal line electrically connected to the first portion and a first-second signal line electrically connected to the second portion.

12. The display device of claim 11, wherein the input sensor further comprises a sensing controller disposed adjacent to a lower portion of the first area in the second direction, and
wherein the first area is disposed between the second area and the sensing controller.

13. The display device of claim 12, wherein each of the first sensing electrodes comprises a plurality of first sensing patterns arranged in the first direction and a plurality of extension patterns extending from the plurality of first sensing patterns,
wherein each of the second sensing electrodes comprises a plurality of second sensing patterns arranged in the second direction and a plurality of bridge patterns electrically connecting the plurality of second sensing patterns to one another,
wherein the first sensing patterns, the plurality of extension patterns, and the second sensing patterns are disposed at a first layer, and the plurality of bridge patterns, the first signal lines, and the second signal lines are disposed at a second layer under the first layer.

14. The display device of claim 13, wherein the first-first signal line is electrically connected to one of the first sensing patterns that is disposed at one end of the first portion adjacent to the sensing controller, and
wherein the first-first signal line does not overlap the first sensing electrodes.

15. The display device of claim 13, wherein the first-second signal line is electrically connected to one of first sensing patterns disposed at the second portion among the first sensing patterns, and
wherein the first-second signal line overlaps the first sensing electrodes.

16. The display device of claim 13, wherein the first-second signal line is electrically connected to one of the first sensing patterns that is disposed at one end of the second portion adjacent to the first portion, and
wherein the first-second signal line overlaps the first sensing electrodes.

17. The display device of claim 1, wherein at least one of the two or more first signal lines extends in the first direction.

18. A display device, comprising:
a display panel displaying an image; and
an input sensor comprising a sensing area comprising a first area and a second area distinguished from the first area in a first direction and a non-sensing area adjacent to the sensing area,
wherein the input sensor comprises:
a first sensing electrode extending in the first direction;
a second sensing electrode extending in a second direction crossing the first direction;
a first-first signal line electrically connected to the first sensing electrode in the first area;
a first-second signal line electrically connected to the first sensing electrode in the second area; and
a second signal line disposed in the non-sensing area and electrically connected to the second sensing electrode, wherein at least one of the first-first and first-second signal lines overlaps the first sensing electrode.

19. The display device of claim 18, wherein the input sensor comprises first conductive patterns disposed on the display panel, a first sensor insulating layer disposed on the first conductive patterns, second conductive patterns disposed on the first sensor insulating layer, and a second sensor insulating layer disposed on the second conductive patterns,
wherein the first sensing electrode comprises the second conductive patterns, and
wherein the first-first and first-second signal lines comprise the first conductive patterns.

20. A display device, comprising:
a display panel displaying an image; and
an input sensor comprising a sensing area comprising a first area, a second area, and a third area, which are distinguished from each other in a first direction and a non-sensing area adjacent to the sensing area,
wherein the input sensor comprises:
a first sensing electrode extending in the first direction and disposed in the first, second, and third areas;
a second sensing electrode extending in a second direction crossing the first direction and disposed in one of the first, second, and third areas;
a first-first signal line disposed in the first area and electrically connected to the first sensing electrode;
a first-second signal line disposed in the second area and electrically connected to the first sensing electrode;
a first-third signal line disposed in the third area and electrically connected to the first sensing electrode; and
a second signal line disposed in the non-sensing area and electrically connected to the second sensing electrode,
wherein at least one of the first-first, first-second, and first-third signal lines overlaps the first sensing electrode.
